(19) United States
(12) Patent Application Publication
(10) Pub. No.: US 2007/0210346 A1
(43) Pub. Date: Sep. 13, 2007

(54) Charge transfer device

(75) Inventor: Keishi Tachikawa, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/714,191

(22) Filed: Mar. 6, 2007

(30) Foreign Application Priority Data
Mar. 7, 2006 (JP) 2006-060388

(51) Int. Cl. H01L 29/768

(52) U.S. Cl. 257/239

(57) ABSTRACT

A gate electrode region of a junction transistor in a signal charge-voltage converter is allowed to have a structure that a gentle potential gradient is formed without generation of a potential barrier. Thus, it is possible to readily realize a signal charge-voltage converter which is high in S/N ratio without generation of reset noise and is excellent in signal charge-voltage conversion efficiency.

### BACKGROUND OF THE INVENTION

(1) Field of the Invention

The present invention relates to a charge transfer device including a junction transistor performing signal charge-voltage conversion.

(2) Description of the Related Art

With regard to a CCD (Charge Coupled Device) for use in a video camera for consumer use or industrial use or a digital still camera increasingly developed in recent years, a cell is finely formed while an output voltage per unit area is secured, in order to achieve reduction in size and enhancement in pixel resolution of such camera. However, the CCD operates in such a manner that a diffusion layer is depleted. Therefore, a scaling rule for fine formation cannot be applied to the CCD, unlike a MOS transistor. That is, the CCD operates by depletion. Therefore, when the cell size is reduced, a cell density must be increased, so that a power supply voltage for depletion disadvantageously exceeds a range of a driving voltage. Therefore, if the cell is finely formed so as to have a size smaller than 2.0 μm, an output voltage appropriate to such reduction in cell size is hardly secured. In order to further reduce a cell size, it is necessary to improve a signal-to-noise (S/N) ratio. In order to improve such S/N ratio, for example, JP62-244174A discloses a signal charge-voltage converter using a junction transistor.

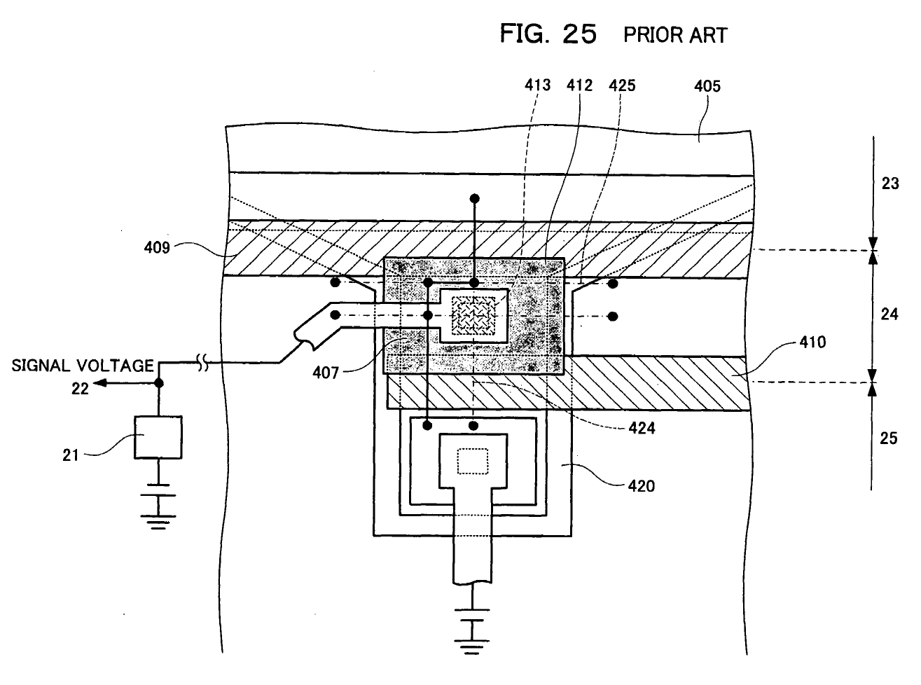

Herein, description will be given of a conventional charge transfer device disclosed in JP62-244174A with reference to FIG. 25.

FIG. 25 is a plan view schematically illustrating the signal charge-voltage converter in the conventional charge transfer device. More specifically, FIG. 25 schematically illustrates the signal charge-voltage converter disclosed in JP62-244174A.

In FIG. 25, the signal charge-voltage converter is a region surrounded with an n-type region 405, an electrode 409, an n-type region 420 and an electrode 410. Herein, the n-type region 405 serves as a horizontal CCD. The electrode 409 is made of polycrystalline silicon and controls a charge transfer amount and a charge transfer operation at a final stage formed on the n-type region 405 with a gate insulating film interposed therebetween. Then-type region 420 serves as a drain discharging signal charge. The electrode 410 is made of polycrystalline silicon and controls a charge discharge amount and a charge discharge operation at the signal charge-voltage converter formed on the n-type region 420 with a gate insulating film interposed therebetween. The signal charge-voltage converter is placed in a signal charge transfer path, and includes an n-type region 407, a p-type region 413 and an electrode 412. Herein, then-type region 407 serves as a gate of a p-type junction transistor. The p-type region 413 serves as a drain, a channel and a source of the p-type junction transistor. The electrode 412 made of polycrystalline silicon is formed on the n-type region 407 with a gate insulating film interposed therebetween in order to control a potential at the n-type region 407 serving as the gate of the p-type junction transistor. The p-type region 413 is formed into a land shape in the n-type region 407. In FIG. 25, a dotted line 425 indicates a line which does not pass through the p-type region 413 in the n-type region 407 and is perpendicular to a signal charge transfer direction. A dotted line 424 indicates a line which passes through the p-type region 413 in the n-type region 407 and is parallel with the signal charge transfer direction.

In the configuration of the conventional signal charge-voltage converter, the p-type region 413 serving as the drain of the p-type junction transistor is formed into a land shape in the n-type region 407 serving as the gate of the p-type junction transistor, and the electrode 412 is formed on the n-type region 407 with the gate insulating film interposed therebetween. Consequently, the n-type region 407 is formed between the n-type region 405 and the p-type region 413, and is located immediately below the electrode 409. In the n-type region 407, as a result, a potential at a region interposed between the n-type region 405 and the p-type region 413 becomes highest and a potential barrier is generated upon performance of charge discharge, so that signal charge cannot be discharged from the signal charge-voltage converter. Consequently, there arise problems of generation of reset noise and degradation in S/N ratio.

### SUMMARY OF THE INVENTION

The present invention is devised in order to solve the aforementioned conventional problems. An object of the present invention is to provide a charge transfer device having a signal charge-voltage converter capable of realizing excellent signal charge-voltage conversion efficiency at a high S/N ratio without generation of reset noise.

In order to accomplish this object, the present invention provides a charge transfer device including: a semiconductor substrate; a horizontal transfer CCD transferring received signal charge in a horizontal direction; a signal charge-voltage converter converting the signal charge transferred from the horizontal transfer CCD into a signal voltage; and a reset drain discharging the signal charge, the horizontal transfer CCD, the signal charge-voltage converter and the reset drain being formed on the semiconductor substrate while adjoining to each other, wherein the signal charge-voltage converter includes: a first conductive type first diffusion layer selectively formed on a surface of the semiconductor substrate; a second conductive type first diffusion layer formed on the surface of the semiconductor substrate so as to come into contact with one of ends of the first conductive type first diffusion layer; a second conductive type second diffusion layer formed on the surface of the semiconductor substrate so as to come into contact with the other end of the first conductive type first diffusion layer; a first gate electrode entirely formed over the first conductive type first diffusion layer, the second conductive type first diffusion layer and the second conductive type second diffusion layer with a first insulating film interposed therebetween; a second gate electrode formed at one of ends of the first gate electrode and on the first insulating film with a second insulating film interposed therebetween; and a third gate electrode formed at the other end of the first gate electrode and on the first insulating film with the second insulating film interposed therebetween, and the first conductive type first diffusion layer extends to a portion located immediately below one of the second and third gate electrodes.

Herein, the first conductive type first diffusion layer extends to portions located immediately below both the second and third gate electrodes.

The present invention also provides a charge transfer device including: a semiconductor substrate; a horizontal transfer CCD transferring received signal charge in a horizontal direction; a signal charge-voltage converter converting the signal charge transferred from the horizontal transfer CCD into a signal voltage; and a reset drain discharging the signal charge, the horizontal transfer CCD, the signal charge-voltage converter and the reset drain being formed on the semiconductor substrate while adjoining to each other, wherein the signal charge-voltage converter includes: a first conductive type first diffusion layer selectively formed on a surface of the semiconductor substrate; a second conductive type first diffusion layer formed on the surface of the semiconductor substrate so as to come into contact with one of ends of the first conductive type first diffusion layer; a second conductive type second diffusion layer formed on the surface of the semiconductor substrate so as to come into contact with the other end of the first conductive type first diffusion layer; a first gate electrode entirely formed over the first conductive type first diffusion layer, the second conductive type first diffusion layer and the second conductive type second diffusion layer with a first insulating film interposed therebetween; a second gate electrode formed at one of ends of the first gate electrode and on the first insulating film with a second insulating film interposed therebetween, the second gate electrode having a triangular notch formed at a center thereof adjoining to the first gate electrode; and a third gate electrode formed at the other end of the first gate electrode and on the first insulating film with the second insulating film interposed therebetween, the end of the first conductive type first diffusion layer is formed into a triangular shape corresponding with the triangular notch of the second gate electrode, and the triangular notch of the second gate electrode has a side face opposing that of the triangular end of the first conductive type first diffusion layer in parallel, with the first insulating film interposed therebetween.

Herein, the third gate electrode has a triangular notch formed at a center thereof adjoining to the first gate electrode, the end of the first conductive type first diffusion layer is formed into a triangular shape corresponding with the triangular notch of the third gate electrode, and the triangular notch of the third gate electrode has a side face opposing that of the triangular end of the first conductive type first diffusion layer in parallel, with the first insulating film interposed therebetween.

The present invention also provides a charge transfer device including: a semiconductor substrate; a horizontal transfer CCD transferring received signal charge in a horizontal direction; a signal charge-voltage converter converting the signal charge transferred from the horizontal transfer CCD into a signal voltage; and a reset drain discharging the signal charge, the horizontal transfer CCD, the signal charge-voltage converter and the reset drain being formed on the semiconductor substrate while adjoining to each other, wherein the signal charge-voltage converter includes: a first conductive type first diffusion layer selectively formed on a surface of the semiconductor substrate; a first conductive type second diffusion layer formed at a deep portion of the semiconductor substrate so as to come into contact with the first conductive type first diffusion layer; a second conductive type first diffusion layer formed on the surface of the semiconductor substrate so as to come into contact with one of ends of the first conductive type first diffusion layer and to come into contact with the first conductive type second diffusion layer formed immediately therebelow; a second conductive type second diffusion layer formed so as to come into contact with an end of the second conductive type first diffusion layer opposite to an end coming into contact with the first conductive type first diffusion layer; a second conductive type third diffusion layer formed on the surface of the semiconductor substrate so as to come into contact with an end of the first conductive type first diffusion layer opposite to the end coming into contact with the second conductive type first diffusion layer and to come into contact with the first conductive type second diffusion layer formed immediately therebelow; a second conductive type fourth diffusion layer formed so as to come into contact with an end of the second conductive type third diffusion layer opposite to the end coming into contact with the first conductive type first diffusion layer; a first conductive type third diffusion layer formed on the surface of the semiconductor substrate so as to come into contact with the second conductive type first diffusion layer, the second conductive type second diffusion layer, the second conductive type third diffusion layer and the second conductive type fourth diffusion layer and to come into contact with the first conductive type second diffusion layer formed immediately therebelow; and a gate electrode entirely formed over the second conductive type first diffusion layer, the second conductive type second diffusion layer, the second conductive type third diffusion layer and the second conductive type fourth diffusion layer with an insulating film interposed therebetween.

Herein, the first conductive type diffusion layer is a p-type diffusion layer and the second conductive type diffusion layer is an n-type diffusion layer.

Alternatively, the first conductive type diffusion layer is an n-type diffusion layer and the second conductive type diffusion layer is a p-type diffusion layer.

### BRIEF DESCRIPTION OF THE INVENTION

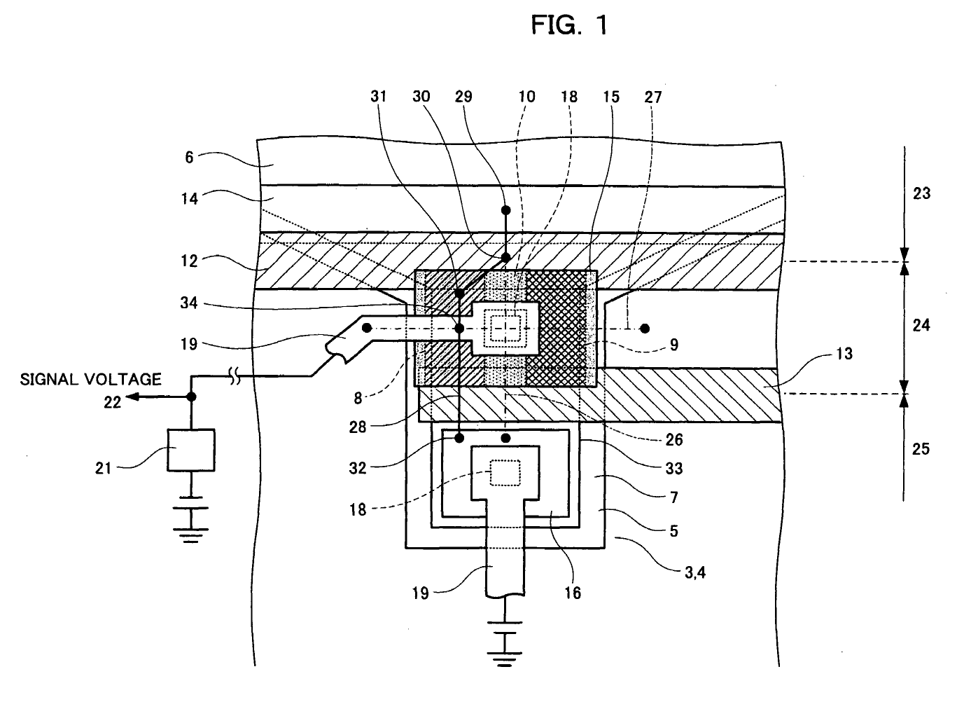

FIG. 1 is a plan view schematically illustrating a signal charge-voltage converter in a charge transfer device according to a first embodiment of the present invention;

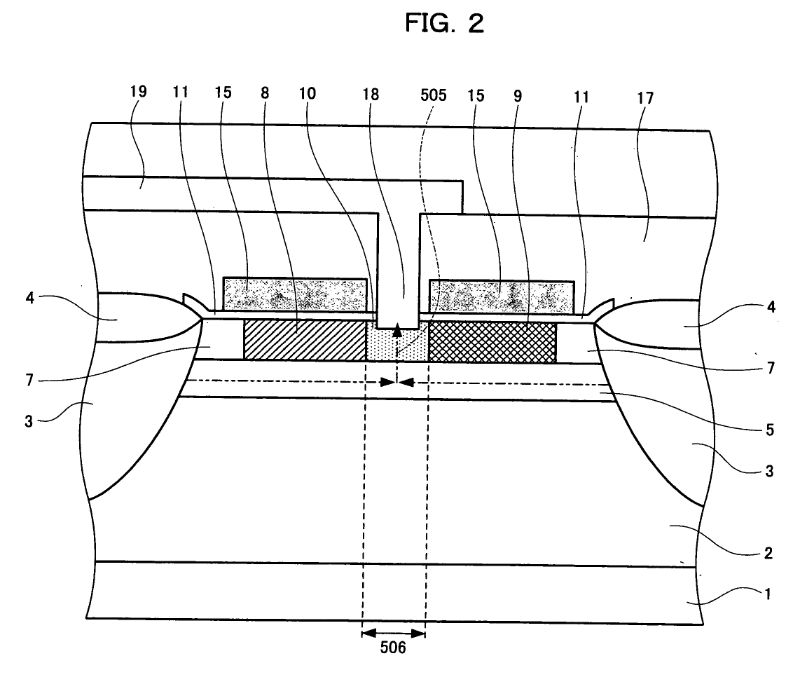

FIG. 2 is a sectional view illustrating the signal charge-voltage converter in the charge transfer device according to the first embodiment, in a direction perpendicular to a charge transfer direction;

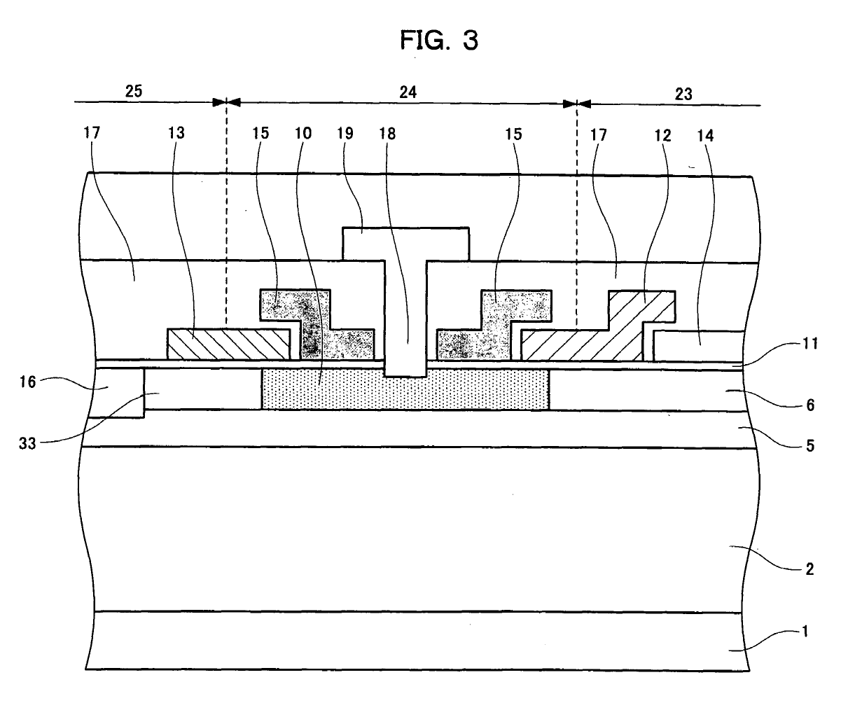

FIG. 3 is a sectional view illustrating the signal charge-voltage converter in the charge transfer device according to the first embodiment, in a direction parallel with the charge transfer direction;

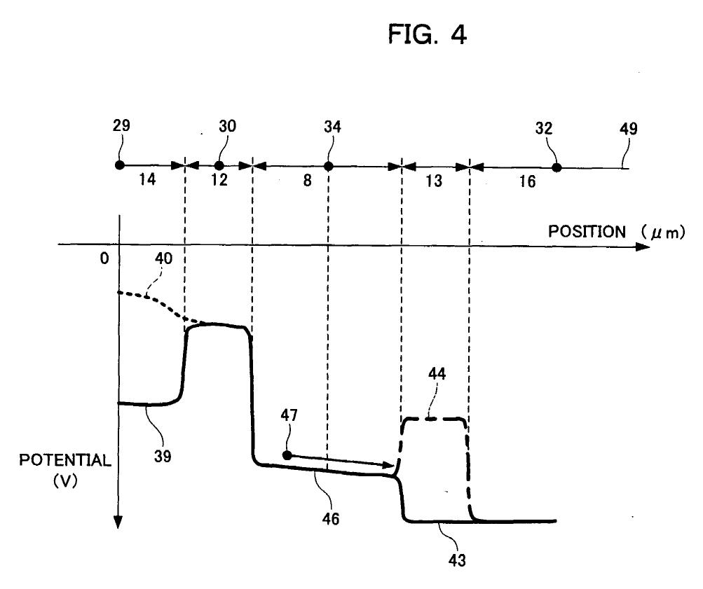

FIG. 4 shows potential distribution in electron transfer performed by the charge transfer device according to the first embodiment;

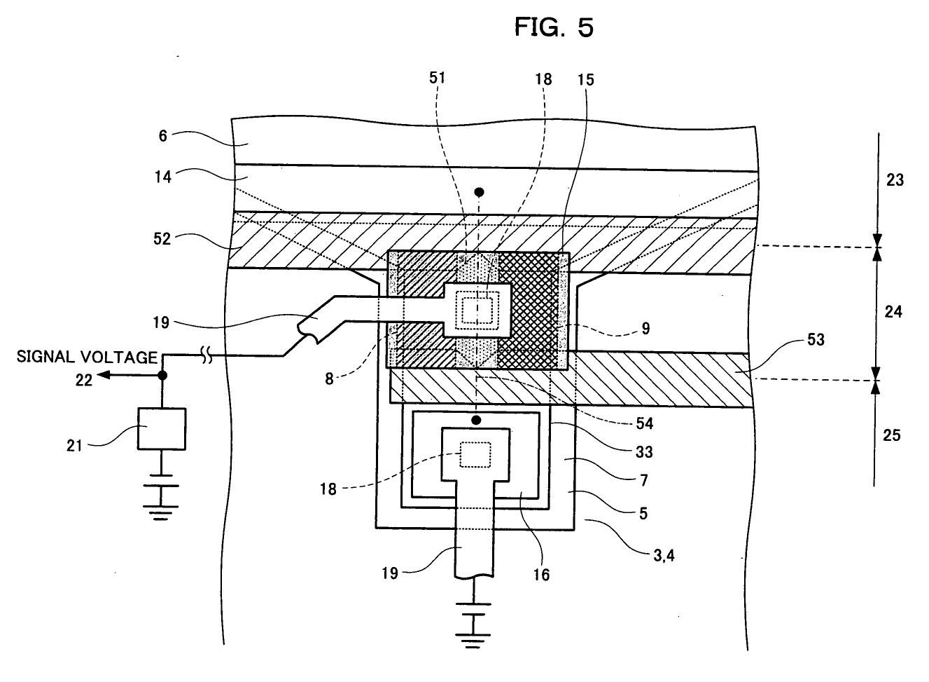

FIG. 5 is a plan view schematically illustrating a signal charge-voltage converter in a charge transfer device according to a second embodiment of the present invention;

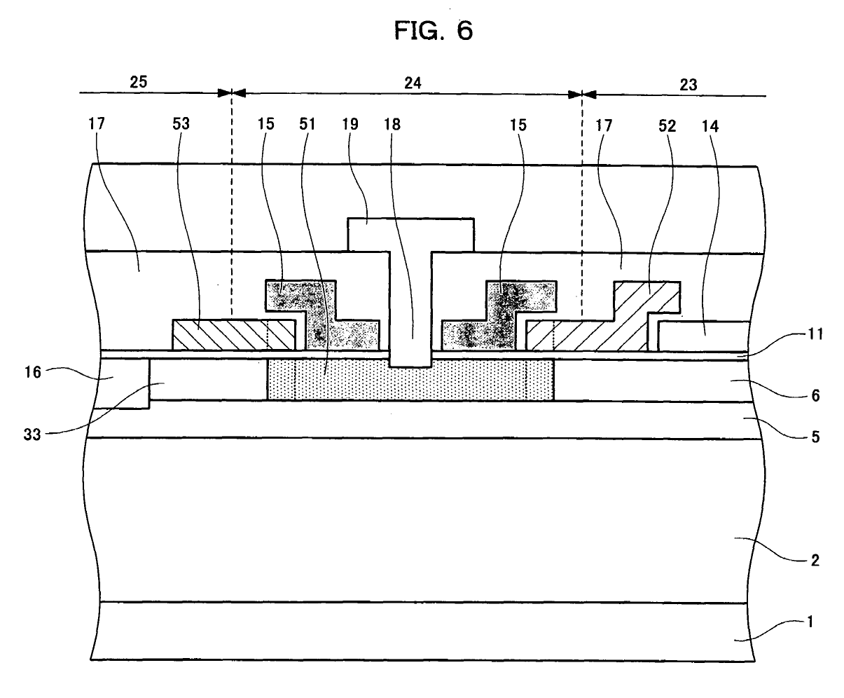

FIG. 6 is a sectional view illustrating the signal charge-voltage converter in the charge transfer device according to the second embodiment, in a direction parallel with a charge transfer direction;

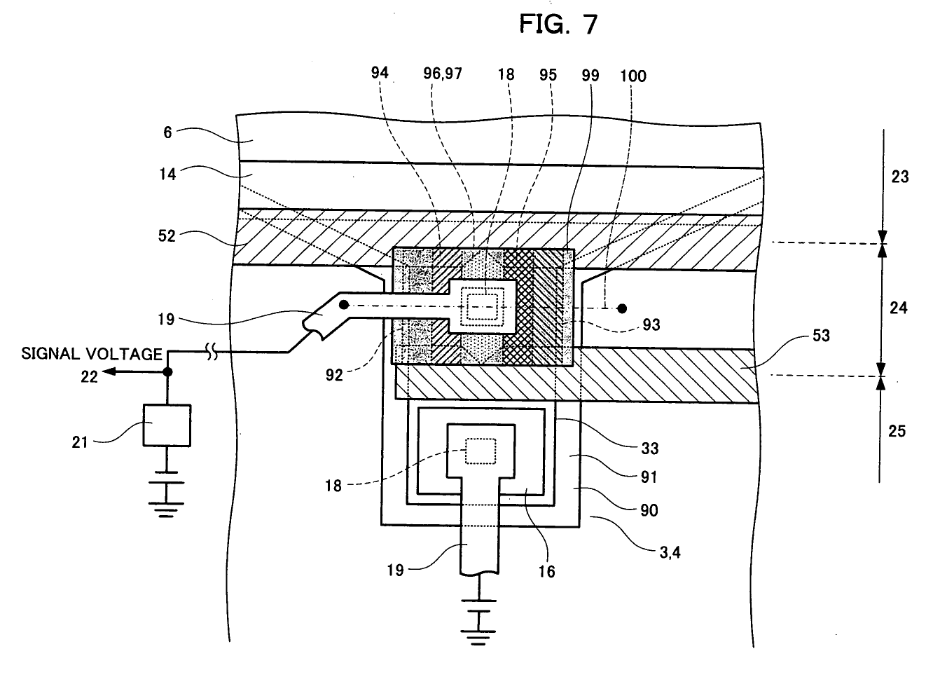

FIG. 7 is a plan view schematically illustrating a signal charge-voltage converter in a charge transfer device according to a third embodiment of the present invention;

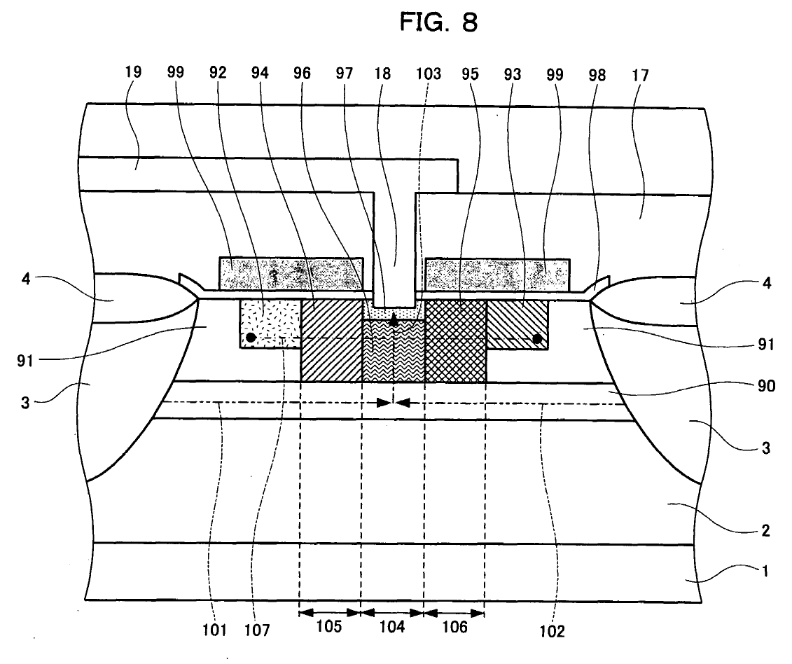

FIG. 8 is a sectional view illustrating the signal charge-voltage converter in the charge transfer device according to the third embodiment, in a direction perpendicular to a charge transfer direction;

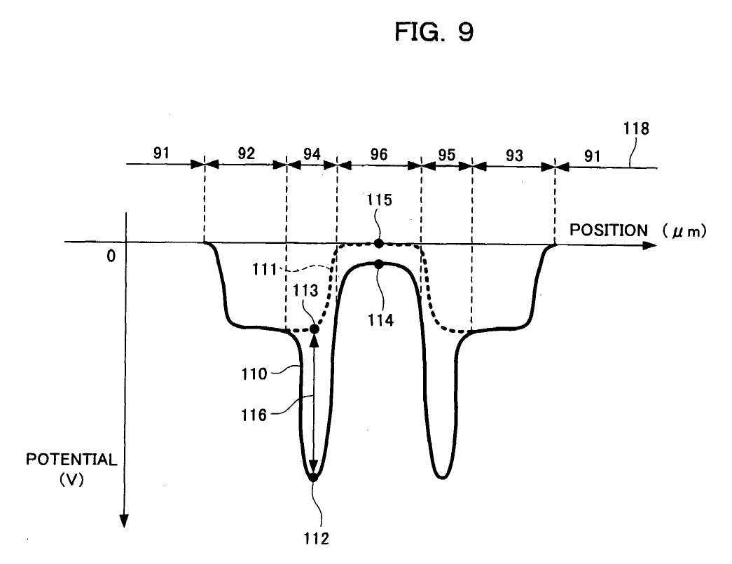

FIG. 9 shows potential distribution in signal conversion performed by the charge transfer device according to the third embodiment;

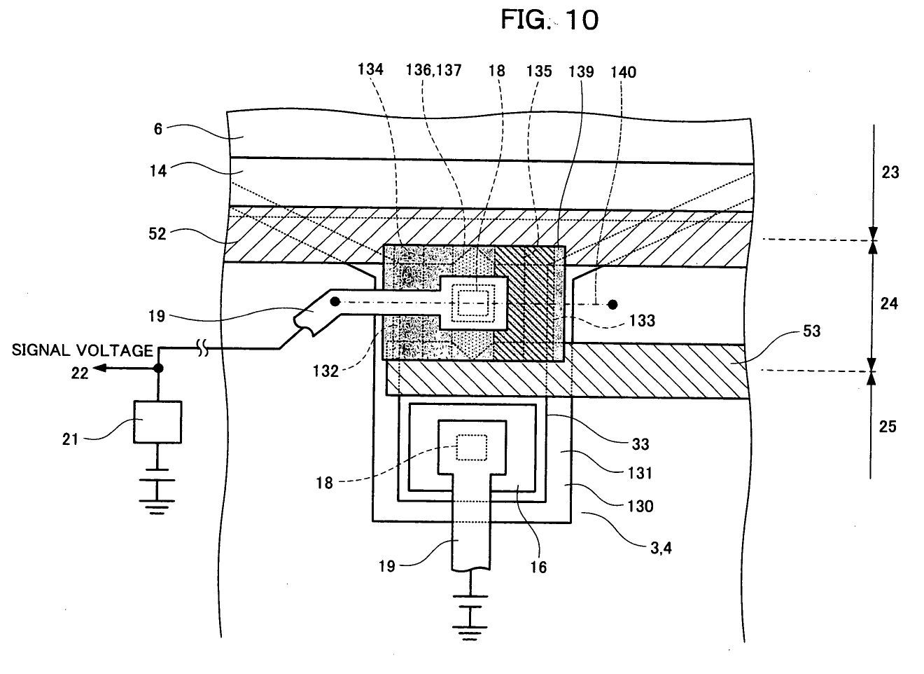

FIG. 10 is a plan view schematically illustrating a signal charge-voltage converter in a charge transfer device according to a fourth embodiment of the present invention;

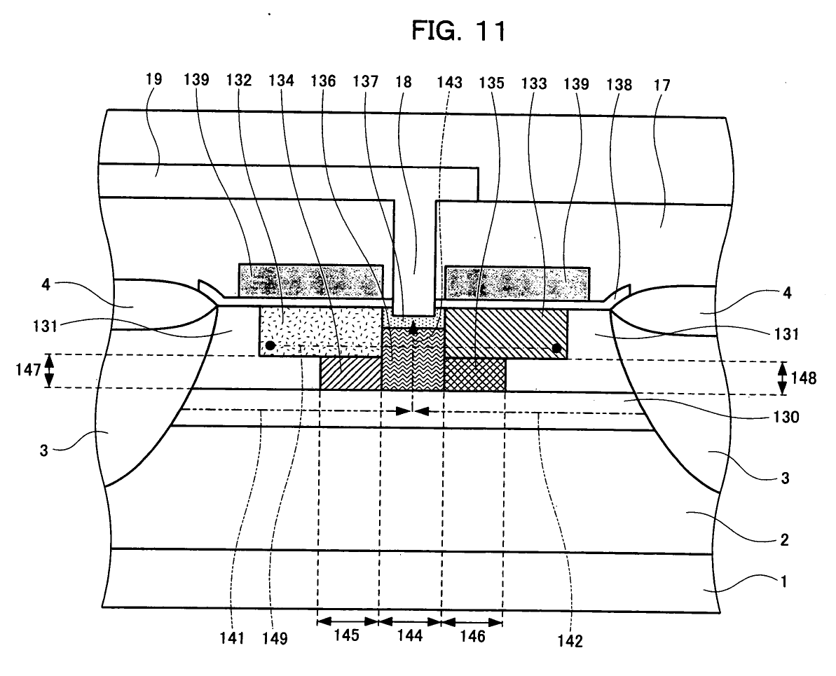

FIG. 11 is a sectional view illustrating the signal charge-voltage converter in the charge transfer device according to the fourth embodiment, in a direction perpendicular to a charge transfer direction;

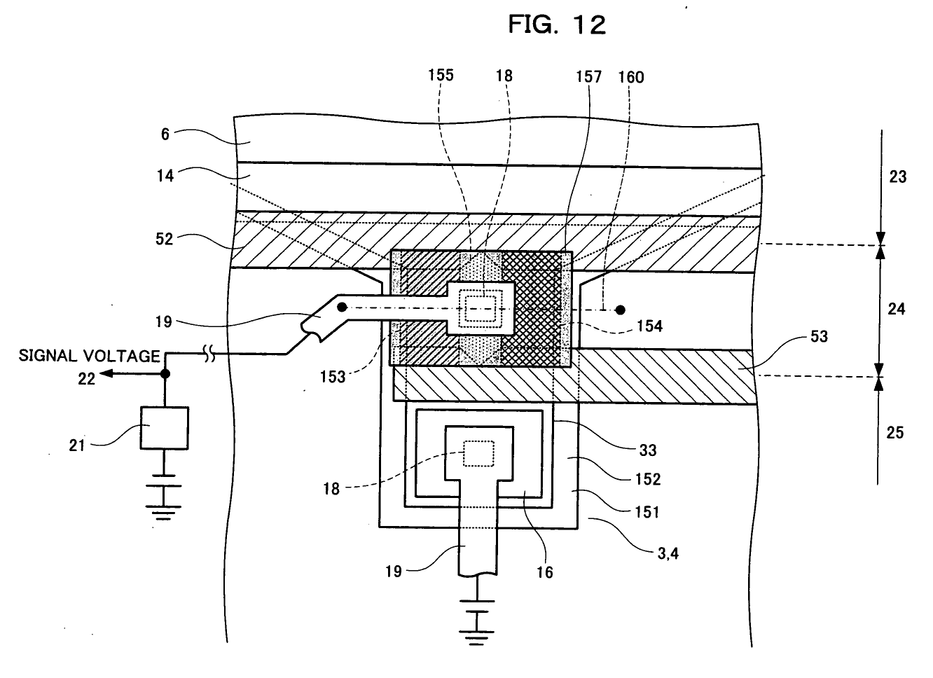

FIG. 12 is a plan view schematically illustrating a signal charge-voltage converter in a charge transfer device according to a fifth embodiment of the present invention;

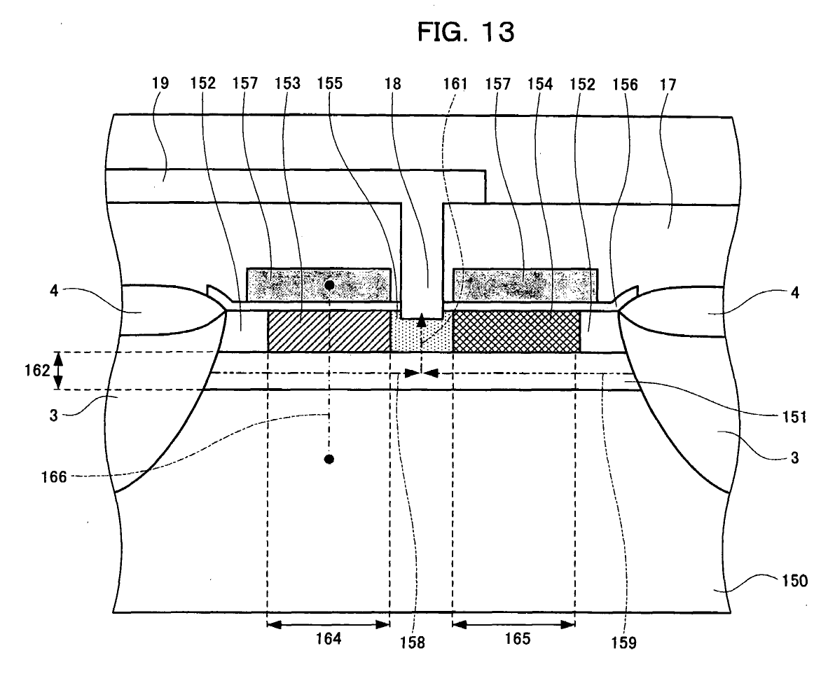

FIG. 13 is a sectional view illustrating the signal charge-voltage converter in the charge transfer device according to the fifth embodiment, in a direction perpendicular to a charge transfer direction;

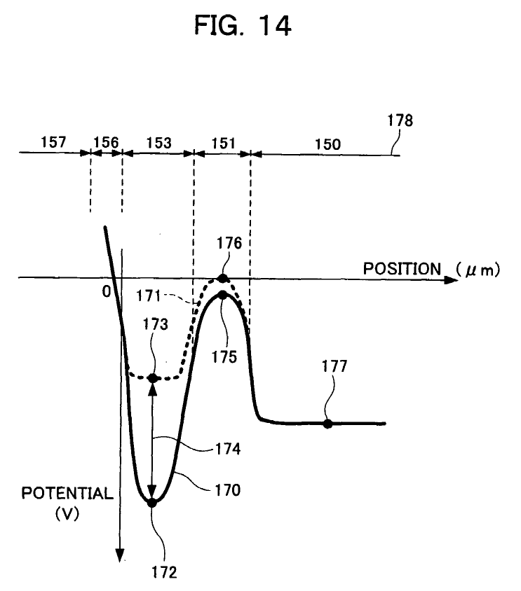

FIG. 14 shows potential distribution in signal conversion performed by the charge transfer device according to the fifth embodiment;

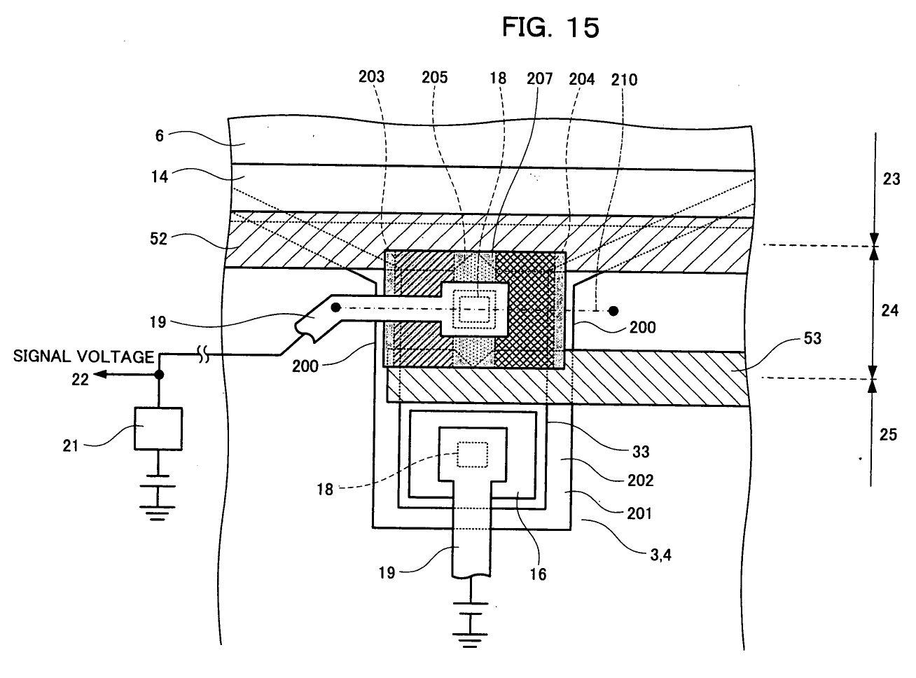

FIG. 15 is a plan view schematically illustrating a signal charge-voltage converter in a charge transfer device according to a sixth embodiment of the present invention;

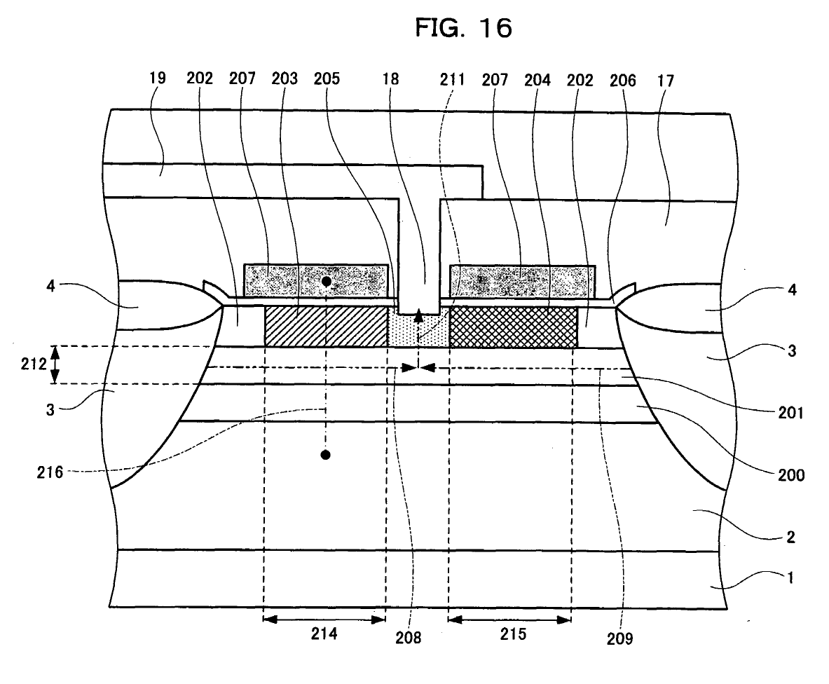

FIG. 16 is a sectional view illustrating the signal charge-voltage converter in the charge transfer device according to the sixth embodiment, in a direction perpendicular to a charge transfer direction;

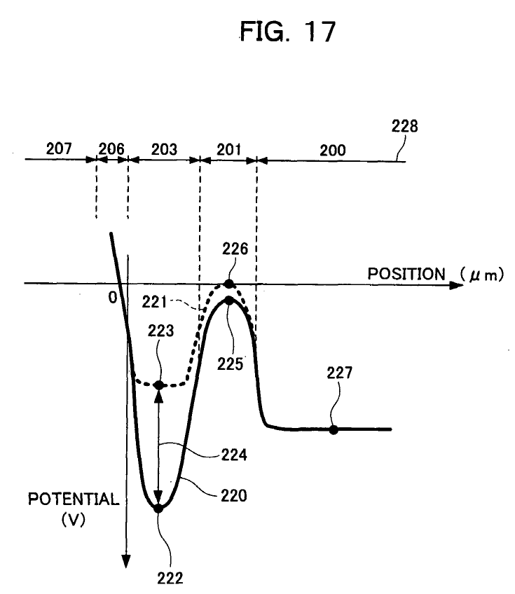

FIG. 17 shows potential distribution in signal conversion performed by the charge transfer device according to the sixth embodiment;

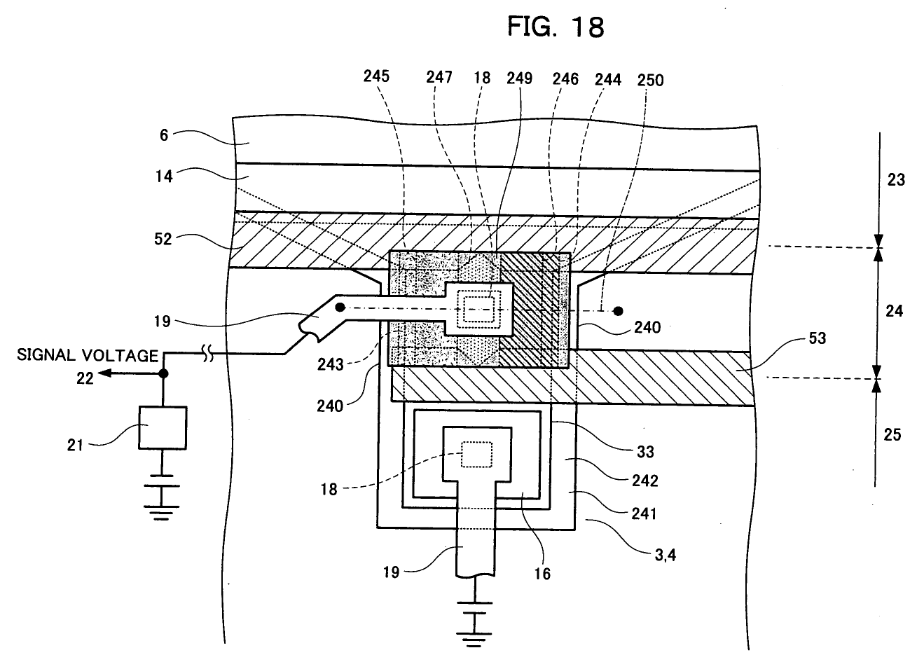

FIG. 18 is a plan view schematically illustrating a signal charge-voltage converter in a charge transfer device according to a seventh embodiment of the present invention;

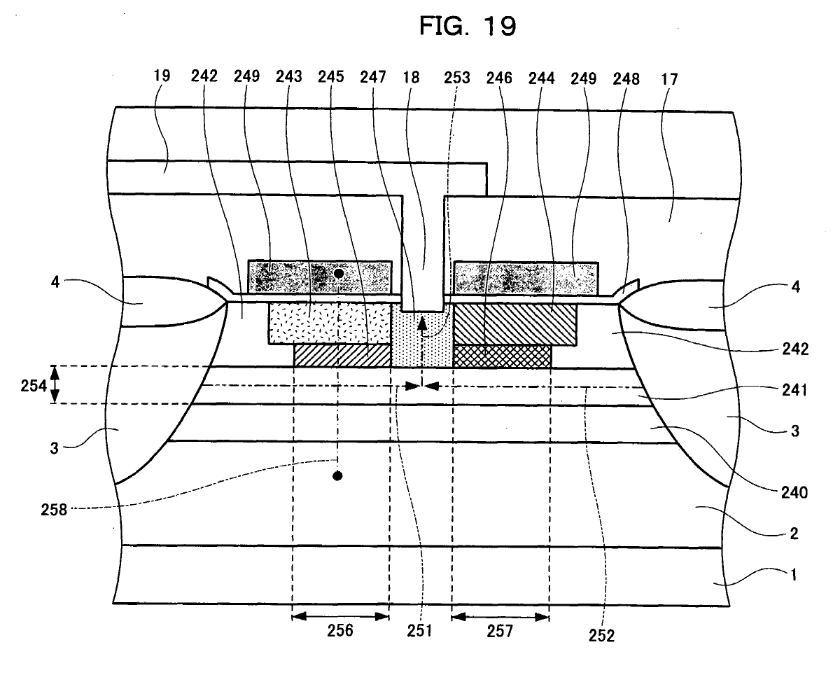

FIG. 19 is a sectional view illustrating the signal charge-voltage converter in the charge transfer device according to the seventh embodiment, in a direction perpendicular to a charge transfer direction;

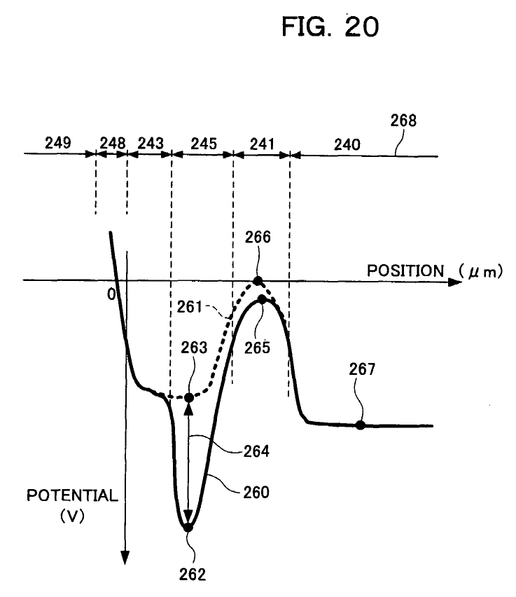

FIG. 20 shows potential distribution in signal conversion performed by the charge transfer device according to the seventh embodiment;

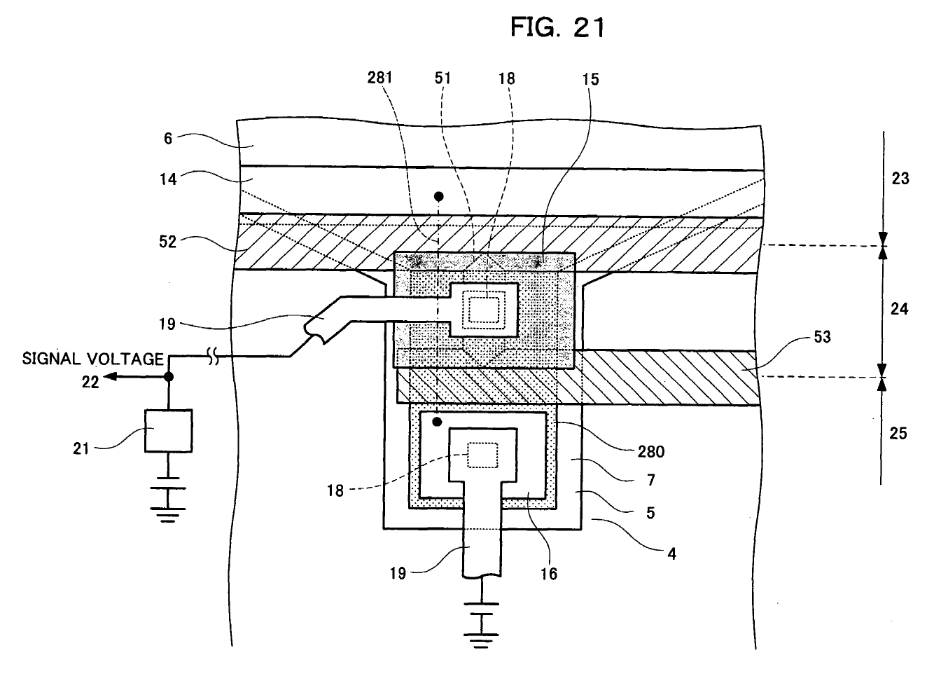

FIG. 21 is a plan view schematically illustrating a signal charge-voltage converter in a charge transfer device according to an eighth embodiment of the present invention;

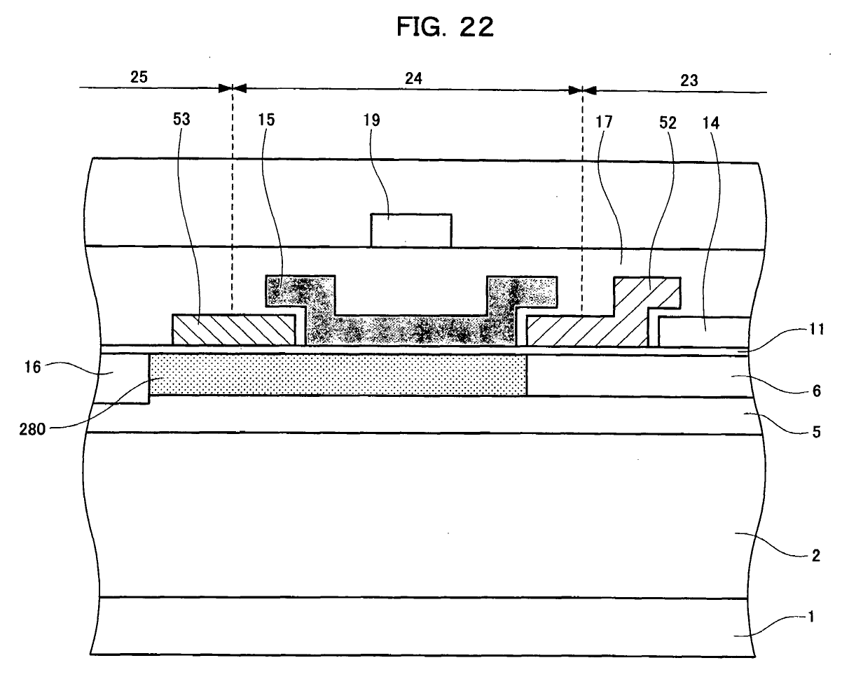

FIG. 22 is a sectional view illustrating the signal charge-voltage converter in the charge transfer device according to the eighth embodiment, in a direction parallel with a charge transfer direction;

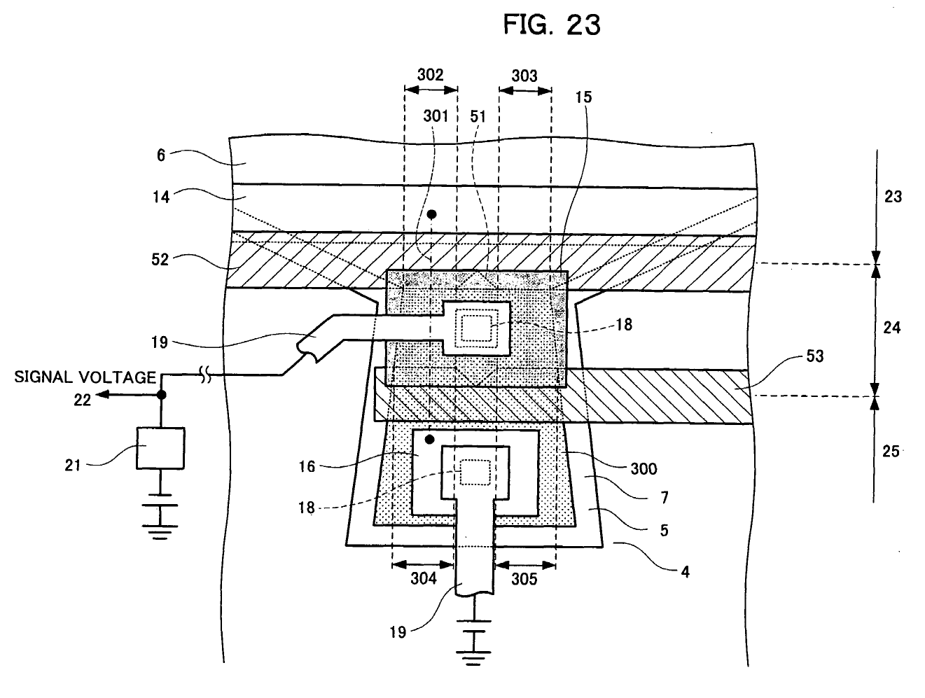

FIG. 23 is a plan view schematically illustrating a signal charge-voltage converter in a charge transfer device according to a ninth embodiment of the present invention;

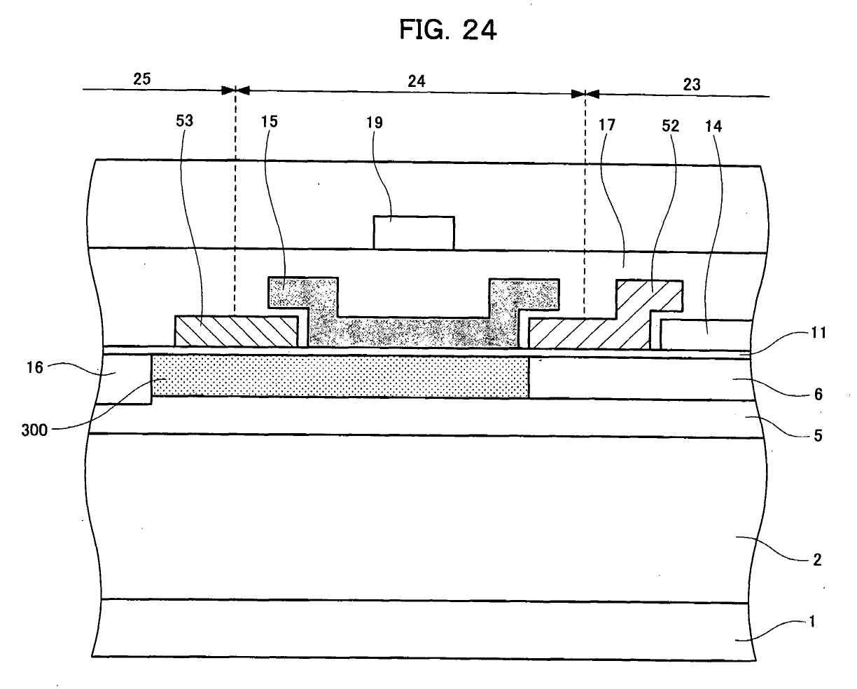

FIG. 24 is a sectional view illustrating the signal charge-voltage converter in the charge transfer device according to the ninth embodiment, in a direction parallel with a charge transfer direction; and

FIG. 25 is a plan view schematically illustrating a signal charge-voltage converter in a conventional charge transfer device.

### DESCRIPTION OF THE PREFERRED EMBODIMENTS

A charge transfer device according to the present invention includes a signal charge-voltage converter. The signal charge-voltage converter includes a first conductive type first diffusion layer selectively formed on a surface of a semiconductor substrate, a second conductive type first diffusion layer formed on the surface of the semiconductor substrate so as to come into contact with one of ends of the first conductive type first diffusion layer, a second conductive type second diffusion layer formed on the surface of the semiconductor substrate so as to come into contact with the other end of the first conductive type first diffusion layer, a first gate electrode entirely formed over the first conductive type first diffusion layer, the second conductive type first diffusion layer and the second conductive type second diffusion layer on the surface of the semiconductor substrate with a first insulating film interposed therebetween, and second and third gate electrodes formed at both ends of the first gate electrode, respectively, and on the first insulating film with a second insulating film interposed therebetween. Herein, the first conductive type first diffusion layer extends to a portion located immediately below one of the second and third gate electrodes. Thus, the signal charge-voltage converter is excellent in signal charge-voltage conversion efficiency at a high S/N ratio without generation of reset noise.

Hereinafter, description will be given of preferred embodiments of the present invention with reference to the drawings.

### First Embodiment

FIG. 1 is a plan view schematically illustrating a signal charge-voltage converter in a charge transfer device according to a first embodiment of the present invention. In FIG. 1, the charge transfer device according to the first embodiment includes a transfer channel and a reset drain in addition to the signal charge-voltage converter. FIG. 2 is a sectional view illustrating the signal charge-voltage converter in the charge transfer device according to the first embodiment, in a direction perpendicular to a charge transfer direction. More specifically, FIG. 2 illustrates a section including an n-type region 8, an n-type region 9, a p-type region 5, a p-type region 10 and a contact 18, in a direction 27 perpendicular to the charge transfer direction. FIG. 3 is a sectional view illustrating the signal charge-voltage converter in the charge transfer device according to the first embodiment, in a direction parallel with the charge transfer direction. More specifically, FIG. 3 illustrates a section including the p-type region 10, in a direction 26 parallel with the charge transfer direction. Herein, description will be given of a configuration of the charge transfer device in a three-dimensional manner with reference to FIGS. 1 to 3.

In FIG. 1, a region 23 includes an n-type region 6, a p-type region 3, the p-type region 5, a gate electrode 14 and a gate electrode 12, and corresponds to a horizontal CCD outlet for feeding signal charge from a horizontal CCD into a signal-charge voltage converter. A region 25 includes an n-type region 16, an n-type region 33, the p-type region 5 and a gate electrode 13, and corresponds to a reset drain for discharging signal charge from the signal-charge voltage converter. A region 24 is sandwiched between the regions 23 and 25, corresponds to the signal charge-voltage converter, and includes the n-type region 8, the n-type region 9, the p-type region 5, the p-type region 10 and a gate electrode 15. A broken curve 28 indicates a transfer channel for electrons (signal charge). Herein, electrons are transferred from the region 23 corresponding to the horizontal CCD to the region 25 corresponding to the reset drain performing discharge of the electrons, through the region 24 corresponding to the signal-charge voltage converter. In the electron transfer channel indicated by the broken line 28, a position 29 is located immediately below the gate electrode 14, a position 30 is located immediately below the gate electrode 12, a position 31 is located in proximity to the gate electrode 12 in the n-type region 8, a position 34 is located at an almost center of the n-type region 8, and a position 32 is located in the n-type region 16 serving as the reset drain. Herein, the position 34 is also located in the section in the direction 27.

In FIG. 2, a p-type well 2 having a low concentration is formed on an n-type semiconductor substrate (hereinafter, simply referred to as “substrate”) 1. The p-type well 2 has an impurity concentration of not less than about 1×10¹⁴ cm⁻³ in order to suppress backflow of electrons from the substrate 1. This impurity concentration brings about the following advantage. That is, even when a power supply voltage (e.g., 15 V or 12 V) is applied to the n-type regions 8 and 9 in a reset operation for electron discharge, backflow of electrons from the substrate 1 is prevented. The p-type region 5, that is, the p-type well is selectively formed on the p-type well 2 on an Si surface side of the substrate 1. The p-type region 10 is formed on the surface of the substrate 1 so as to come into contact with the p-type region 5. The n-type region 8 is formed on the surface of the substrate 1 so as to come into contact with one of ends of the p-type region 10. Herein, the n-type region 8 is surrounded with the p-type region 3, the p-type region 10 and the p-type region 7. The n-type region 9 is formed on the surface of the substrate 1 so as to come into contact with the other end of the p-type region 10. Herein, the n-type region 9 is surrounded with the p-type region 3, the p-type region 10 and the p-type region 7. The p-type region 10 serves as a channel and a drain of a junction transistor for performing signal charge-voltage conversion. The p-type region 10 also serves as a contact with the surface of the substrate 1. The p-type region 5 serves as a source of the junction transistor. Therefore, the p-type region 5 has an impurity concentration equal to or higher than that of the p-type region 10. Each of the n-type regions 8 and 9 serves as a gate electrode of the junction transistor. The gate electrode 15 is formed for controlling an operating voltage in the junction transistor and for controlling electron transfer from the horizontal CCD. In a case that there is no electron, when a desired voltage is applied to the gate electrode 15, the n-type regions 8 and 9 are depleted. When electrons (signal charge) are fed into the region 23 for voltage conversion, a potential at each of the n-type regions 8 and 9 changes and a channel width 506 of the junction transistor varies. Thus, a channel current 505 in the junction transistor is subjected to modulation, so that a signal voltage 22 is outputted through a load resistor 21 connected by an Al wire 19. This embodiment adopts a lateral transistor structure that an n-type region, that is, a gate electrode is provided beside a channel of a transistor. The p-type regions 5 and 7 come into contact with each other in such a positional relation that the p-type region 7 is located on the p-type region 5 when being seen from the surface of the substrate 1. Herein, each of the p-type regions 5 and 7 comes into contact with the p-type region 3. An oxide film 4 is formed on the p-type region 3 on the surface of the substrate 1. A gate insulating film 11 is formed over the n-type region 8, the n-type region 9, the p-type region 7 and the oxide film 4 on the surface of the substrate 1. The gate electrode 15 is formed immediately above the gate insulating film 11 so as to entirely cover the n-type regions 8 and 9 and to partially cover the p-type region 7. Further, an oxide film 17 is formed on the gate electrode 15 so as to entirely cover the substrate 1. In order to form a contact in the p-type region 10, the oxide film 17 is perforated; thus, the contact 18 is formed in the p-type region 10. Then, the contact 18 is filled with Al to selectively form the Al wire 19. A protective film is entirely formed so as to protect the Al wire 19.

In FIG. 3, the horizontal CCD transfer channel is then-type region 6 selectively formed on a surface of the p-type region 5. The final gate electrode 14 of the horizontal CCD is formed on the n-type region 6 with the gate insulating film 11 interposed therebetween, and the gate electrode 12 is formed adjacent to the gate electrode 14 with the oxide film 17 interposed therebetween. The n-type region 16 serving as the reset drain is formed so as to come into contact with the n-type region 33 selectively formed on the surface of the p-type region 5. The gate electrode 13 is selectively formed on the n-type region 33 on the surface of the substrate 1 with the gate insulating film 11 interposed therebetween.

The p-type region 10 serves as the channel and the drain of the junction transistor, and is connected to a power supply by the contact 18 through the Al wire 19. The n-type region 33 and the n-type region 6 are formed at both ends of the p-type region 10, respectively. Further, the p-type region 5 is formed immediately below the p-type region 10. In other words, the p-type region 10 is selectively formed on the surface of the substrate 1 so as to be surrounded with the n-type region 33, the n-type region 6 and the p-type region 5. Herein, two gate electrodes 15 are formed on the p-type region 10 with the gate insulating film 11 interposed therebetween. One of the gate electrodes 15 has one of ends coming into contact with the gate electrode 12 with the oxide film 17 interposed therebetween and the other end coming into contact with the Al wire 19 with the oxide film 17 interposed therebetween. The other gate electrode 15 has one of ends coming into contact with the Al wire 19 with the oxide film 17 interposed therebetween and the other end coming into contact with the gate electrode 13 with the oxide film 17 interposed therebetween. The p-type region 10 has one of ends extending beyond a portion located immediately below the gate electrode 15 to a portion located immediately below the gate electrode 12, and the other end extending beyond a portion located immediately below the gate electrode 15 to a portion located immediately below the gate electrode 13. Thus, the p-type region 10 can serve as the channel and the drain of the junction transistor and the contact. In addition, the p-type region 10 can reduce remaining electrons in the signal-charge voltage converter after performance of the electron discharge, and can improve an S/N ratio.

Thus, it is possible to configure a signal charge-voltage converter having a junction transistor capable of readily improving an S/N ratio.

Next, description will be given of a mechanism for improving an S/N ratio with reference to FIGS. 1 to 4.

FIG. 4 shows potential distribution in electron transfer performed by the charge transfer device according to the first embodiment.

In a case that electrons (signal charge) are transferred from the horizontal CCD to the reset drain through the signal charge-voltage converter, a transfer channel is formed along the broken curve 28 illustrated in FIG. 1. FIG. 4 shows potential distribution in the electron transfer along the broken-curve 28. In FIG. 4, a straight line 49 indicates a region at each position along the broken curve 28. At a position 29 that electrons are transferred from the region 23 corresponding to the horizontal CCD to the region 24 corresponding to the signal charge-voltage converter, the gate electrodes 14 and 13 are turned off. As a result, a potential at the transfer channel changes from a solid line 39 to a dotted line 40 at a portion located immediately below the gate electrode 14. Further, the potential changes from a solid line 43 to a dotted line 44 at a portion located immediately below the gate electrode 13. The n-type region 8 incurs no influence by the gate electrodes 12 and 13; therefore, a potential thereat does not change. The p-type region 10 extends to a portion located immediately below at least one of the gate electrodes 12 and 13. In the region 24 corresponding to the signal charge-voltage converter, therefore, the n-type region 8 and the n-type region 9 are formed at the both ends of the p-type region 10, respectively, in the electron transfer direction, as illustrated in FIG. 1. In addition, the n-type region 16 in the region 25 corresponding to the reset drain is applied with a power supply voltage. In the n-type region 8, therefore, no potential barrier is generated, but a gentle potential gradient 46 is formed toward the region 25. In a case that electrons are discharged from the region 24, accordingly, the gate electrode 13 is turned on, so that the potential returns to the solid line 43. Thus, electrons 47 (signal charge) can be completely discharged to the n-type region 16 serving as the reset drain. Thus, it is possible to achieve a high S/N ratio without remaining electrons in electron transfer and electron discharge. Moreover, by the formation of the gate electrode 15, the potentials at the n-type regions 8 and 9, each serving as the gate electrode of the junction transistor, can be set freely, so that a transistor for a signal charge-voltage converter can be readily realized. Thus, it is possible to configure a signal charge-voltage converter having a junction transistor capable of eliminating remaining electrons in electron transfer and electron discharge and readily improving an S/N ratio.

According to the first embodiment, as described above, a signal charge-voltage converter includes a first conductive type first diffusion layer selectively formed on a surface of a semiconductor substrate, a second conductive type first diffusion layer formed on the surface of the semiconductor substrate so as to come into contact with one of ends of the first conductive type first diffusion layer, a second conductive type second diffusion layer formed on the surface of the semiconductor substrate so as to come into contact with the other end of the first conductive type first diffusion layer, a first gate electrode entirely formed over the first conductive type first diffusion layer, the second conductive type first diffusion layer and the second conductive type second diffusion layer on the surface of the semiconductor substrate with a first insulating film interposed therebetween, and second and third gate electrodes formed at both ends of the first gate electrode, respectively, and on the first insulating film with a second insulating film interposed therebetween. Herein, the first conductive type first diffusion layer extends to a portion located immediately below one of the second and third gate electrodes. Thus, it is possible to configure a signal charge-voltage converter having a junction transistor capable of eliminating remaining electrons in electron transfer and electron discharge and readily improving an S/N ratio.

### Second Embodiment

FIG. 5 is a plan view schematically illustrating a signal charge-voltage converter in a charge transfer device according to a second embodiment of the present invention. In FIG. 2, the charge transfer device according to the second embodiment includes a transfer channel and a reset drain in addition to the signal charge-voltage converter. FIG. 6 is a sectional view illustrating the signal charge-voltage converter in the charge transfer device according to the second embodiment, in a direction parallel with a charge transfer direction. More specifically, FIG. 6 illustrates a section including a p-type region 51, in a direction 54 parallel with the charge transfer direction. In FIGS. 5 and 6, constituent elements equal to those in FIGS. 1 to 4 are not described in detail herein.

In FIG. 5, a region 23 includes an n-type region 6, a p-type region 5, a gate electrode 14 and a gate electrode 52, and corresponds to a horizontal CCD outlet. A region 25 includes an n-type region 33, an n-type region 16, the p-type region 5 and a gate electrode 53, and corresponds to a reset drain. A region 24 is sandwiched between the regions 23 and 25, and corresponds to a signal charge-voltage converter.

In FIG. 6, the horizontal CCD transfer channel is then-type region 6 selectively formed on a surface of the p-type region 5. The target gate electrode 14 for controlling electron transfer at a final stage of the horizontal CCD is selectively formed on the n-type region 6 with a gate insulating film 11 interposed therebetween. The gate electrode 52 is formed on the n-type region 6 with the gate insulating film 11 interposed therebetween so as to adjoin to the gate electrode 14. The gate electrode 52 comes into contact with a gate electrode 15 with an oxide film 17 interposed therebetween. The p-type region 51 is selectively formed on a surface of an n-type semiconductor substrate (hereinafter, simply referred to as “substrate”) 1 so as to be surrounded with the n-type region 6, the n-type region 33 and the p-type region 5. Herein, the n-type region 6 and the n-type region 33 are formed at both ends of the p-type region 51, respectively, and the p-type region 5 is formed immediately below the p-type region 51. The p-type region 51 serves as a drain of a junction transistor for performing signal charge-voltage conversion. The p-type region 51 has a concentration higher than that of the p-type region 5. Herein, two gate electrodes 15 are formed on the p-type region 51 with the gate insulating film 11 interposed therebetween. One of the gate electrodes 15 has one of ends coming into contact with the gate electrode 52 with the oxide film 17 interposed therebetween and the other end coming into contact with an Al wire 19 with the oxide film 17 interposed therebetween. The other gate electrode 15 has one of ends coming into contact with the Al wire 19 with the oxide film 17 interposed therebetween and the other end coming into contact with the gate electrode 53 with the oxide film 17 interposed therebetween. The gate electrode 53 serves as a reset gate for discharging electrons (signal charge) in order to successively extract image signals, and is formed on the n-type region 33 with the gate insulating film 11 interposed therebetween. The p-type region 51 is formed on the surface of the substrate 1 such that both ends thereof are aligned with one of ends of the gate electrode 52 and one of ends of the gate electrode 53, respectively. In order to reduce remaining electrons (signal charge) after performance of electron transfer and to improve an S/N ratio, as illustrated in FIG. 5, at least one of the gate electrode 52 in the region 23 corresponding to the horizontal CCD outlet and the gate electrode 53 in the region 25 corresponding to the reset drain is provided with a triangular notch formed at a center thereof, and the p-type region 51 is formed in the n-type region 33 so as to come into contact with such triangular notch.

When the gate electrode 52 is provided with a triangular notch and the p-type region 51 is formed so as to have one end corresponding with such triangular notch, an electric field can be formed in a direction along p-n junction. Therefore, it is possible to enhance an electric field strength for transferring electrons to n-type regions 8 and 9, at a portion located immediately below the gate electrode 52. Accordingly, it is possible to smoothly transfer electrons from the final stage of the horizontal CCD to the signal charge-voltage converter, and to uniformly distribute signal charge to the n-type regions 8 and 9. Thus, it is possible to configure a signal charge-voltage converter by a junction transistor which causes no transfer degradation and is excellent in signal charge-voltage conversion efficiency.

According to the second embodiment, as described above, a signal charge-voltage converter includes a first conductive type first diffusion layer selectively formed on a surface of a semiconductor substrate, a second conductive type first diffusion layer formed on the surface of the semiconductor substrate so as to come into contact with one of ends of the first conductive type first diffusion layer, a second conductive type second diffusion layer formed on the surface of the semiconductor substrate so as to come into contact with the other end of the first conductive type first diffusion layer, a first gate electrode entirely formed over the first conductive type first diffusion layer, the second conductive type first diffusion layer and the second conductive type second diffusion layer on the surface of the semiconductor substrate with a first insulating film interposed therebetween, and a second gate electrode formed at one of ends of the first gate electrode and on the first insulating film with a second insulating film interposed therebetween, the second gate electrode having a triangular notch formed at a center thereof. Herein, the triangular notch of the second gate electrode is aligned with the end of the first conductive type first diffusion layer. Thus, it is possible to configure a signal charge-voltage converter by a junction transistor which causes no transfer degradation and is excellent in signal charge-voltage conversion efficiency.

### Third Embodiment

FIG. 7 is a plan view schematically illustrating a signal charge-voltage converter in a charge transfer device according to a third embodiment of the present invention. In FIG. 7, the charge transfer device according to the third embodiment includes a transfer channel and a reset drain in addition to the signal charge-voltage converter. FIG. 8 is a sectional view illustrating the signal charge-voltage converter in the charge transfer device according to the third embodiment, in a direction perpendicular to a charge transfer direction. More specifically, FIG. 8 illustrates a section including a p-type region 96, a p-type region 97, an n-type region 92, an n-type region 93, an n-type region 94 and an n-type region 95, in a direction 100 perpendicular to the charge transfer direction. In FIGS. 7 and 8, constituent elements equal to those in FIGS. 1 to 6 are not described in detail herein.

In FIG. 7, a region 23 includes an n-type region 6, a p-type region 90, a p-type region 91, a gate electrode 14 and a gate electrode 52, and corresponds to a horizontal CCD outlet. A region 25 includes an n-type region 33, an n-type region 16, the p-type region 90, the p-type region 91 and a gate electrode 53, and corresponds to a reset drain. A region 24 is sandwiched between the regions 23 and 25, and corresponds to a signal charge-voltage converter. The region 24 includes the n-type region 92, the n-type region 93, the n-type region 94, the n-type region 95, the p-type region 96, the p-type region 97 and a gate electrode 99.

In FIG. 8, the p-type region 90 is selectively formed in a p-type well 2 selectively formed in an n-type semiconductor substrate (hereinafter, simply referred to as “substrate”) 1. The p-type region 91 is selectively formed on a surface of the substrate 1 so as to come into contact with the p-type region 90. An oxide film 4 is selectively formed on the surface of the substrate 1, and a p-type region 3 is formed immediately below the oxide film 4. The p-type region 3 is connected to the p-type regions 90 and 91 in the substrate 1. The p-type region 96 is formed on the surface side of the substrate 1 so as to come into contact with the p-type region 90. The p-type region 97 for a contact with the substrate 1 is formed on the surface of the substrate 1 so as to come into contact with the p-type region 96. Herein, the p-type region 97 has a high concentration. The p-type region 96 serves as a channel of a junction transistor for performing signal charge-voltage conversion. Further, the p-type region 90 and the p-type region 97 serve as a source and a drain of the junction transistor, respectively. The p-type region 90 has an impurity concentration equal to or higher than that of the p-type region 96. The p-type region 97 has an impurity concentration equal to or higher than that of the p-type region 96. The n-type region 94 is formed at one of ends of the p-type regions 96 and 97 on the surface of the substrate 1 so as to come into contact with the p-type regions 96 and 97. The n-type region 95 is formed at the other ends of the p-type regions 96 and 97 on the surface of the substrate 1 so as to come into contact with the p-type regions 96 and 97. The n-type region 92 is formed at an end of the n-type region 94, opposite to an end coming into contact with the p-type regions 96 and 97, on the surface of the substrate 1. The p-type region 91 is formed immediately below the n-type region 92 on the surface of the substrate 1 so as to come into contact with the n-type region 92. In other words, the n-type region 92 is surrounded with the p-type region 91. The n-type region 93 is formed at an end of the n-type region 95, opposite to an end coming into contact with the p-type regions 96 and 97, on the surface of the substrate 1. The p-type region 91 is formed immediately below the n-type region 93 on the surface of the substrate 1 so as to come into contact with the n-type region 93. In other words, the n-type region 93 is surrounded with the p-type region 91.

The p-type region 91 comes into contact with the p-type region 90 at a deep portion of the substrate 1. A pair of the n-type regions 92 and 94 and a pair of n-type regions 93 and 95 serve as gate electrodes of the junction transistor. Particularly, each of the n-type regions 94 and 95 can enhance signal charge-voltage conversion efficiency. Agate insulating film 98 is formed over the n-type region 92, the n-type region 93, the n-type region 94, the n-type region 95, the p-type region 91 and the oxide film 4 on the surface of the substrate 1. The gate electrode 99 is formed immediately above the gate insulating film 98 so as to entirely cover the n-type regions 92 to 95 and to partially cover the p-type region 91. Thus, it is possible to configure a signal charge-voltage converter having a junction transistor capable of readily improving an S/N ratio.

In FIG. 8, chain lines 101 and 102 indicate currents flowing through the source of the junction transistor. A chain line 103 indicates a current flowing through the channel of the junction transistor. A straight line 107 indicates a dotted line passing through the n-type region 92, the n-type region 93, the n-type region 94, the n-type region 95 and the p-type region 96. The straight line 107 is defined so as to include the gate and the channel of the junction transistor. An arrow mark 104 indicates widths of the p-type regions 96 and 97, and corresponds to a channel width of the junction transistor. At the channel width of the junction transistor, signal charge is subjected to voltage modulation. An arrow mark 105 indicates a width of the n-type region 94, and an arrow mark 106 indicates a width of the n-type region 95.

Next, description will be given of a mechanism for improving signal charge-voltage conversion efficiency with reference to FIGS. 7 to 9. FIG. 9 shows potential distribution in signal conversion performed by the charge transfer device according to the third embodiment. More specifically, FIG. 9 shows potential distribution before and after the signal conversion in a region along the straight line 107. In FIG. 9, a straight line 118 indicates a region at each position along the straight line 107. A curve 110 indicates potential distribution before the signal conversion. Electrons (signal charge) fed into the region 24 corresponding to the signal charge-voltage converter are accumulated in the n-type regions 94 and 95 because the potential distribution is deep. Herein, a minimum potential 112 changes into a potential 113, and the potential distribution in the signal conversion varies as indicated by a curve 111. In response thereto, a potential at the p-type region 96 changes from a potential 114 to a potential 115. Thus, a channel current 103 in the junction transistor is modulated, and then is subjected to voltage conversion by an external load resistor 21. When an output voltage is formed at a higher density in such a manner that the widths of the n-type regions 95 and 96 indicated by the arrow marks 105 and 106 are made narrow, a voltage amplitude 116 by the signal charge can be made large. This means that a gate voltage amplitude of the junction transistor can be made large. Therefore, it is possible to enhance signal charge-voltage conversion efficiency. Further, the n-type regions 94 and 95 formed at the both ends of the p-type region 96 accumulate electrons (signal charge) and change potentials thereat. The change in potential at the n-type region 95 directly exerts an influence on the p-type regions 96. Therefore, it is possible to further enhance signal charge-voltage conversion efficiency. Moreover, the widths indicated by the arrow marks 105 and 106 are made small to form an output voltage at a high density. Only by such operation, it is possible to readily configure a junction transistor capable of realizing desired voltage conversion characteristics at high efficiency and improving an S/N ratio.

According to the third embodiment of the present invention, as described above, a signal charge-voltage converter includes a first conductive type first diffusion layer selectively formed on a surface of a semiconductor substrate, a first conductive type second diffusion layer formed at a deep portion of the semiconductor substrate so as to come into contact with the first conductive type first diffusion layer, a second conductive type first diffusion layer formed on the surface of the semiconductor substrate so as to come into contact with one of ends of the first conductive type first diffusion layer and to come into contact with the first conductive type second diffusion layer formed immediately therebelow, a second conductive type second diffusion layer formed so as to come into contact with the second conductive type first diffusion layer at an end opposite to the end coming into contact with the first conductive type first diffusion layer, a second conductive type third diffusion layer formed on the surface of the semiconductor substrate so as to come into contact with the other end of the first conductive type first diffusion layer and to come into contact with the first conductive type second diffusion layer formed immediately therebelow, a second conductive type fourth diffusion layer formed so as to come into contact with the second conductive type third diffusion layer at an end opposite to the end coming into contact with the first conductive type first diffusion layer, a first gate electrode entirely formed over the second conductive type first diffusion layer and the second conductive type second diffusion layer with an insulating film interposed therebetween, and a second gate electrode entirely formed over the second conductive type third diffusion layer and the second conductive type fourth diffusion layer with the insulating film interposed therebetween. Thus, it is possible to readily configure a signal charge-voltage converter having a junction transistor capable of realizing desired voltage conversion characteristics at high efficiency and improving an S/N ratio.

### Fourth Embodiment

FIG. 10 is a plan view schematically illustrating a signal charge-voltage converter in a charge transfer device according to a fourth embodiment of the present invention. In FIG. 10, the charge transfer device according to the fourth embodiment includes a transfer channel and a reset drain in addition to the signal charge-voltage converter. FIG. 11 is a sectional view illustrating the signal charge-voltage converter in the charge transfer device according to the fourth embodiment, in a direction perpendicular to a charge transfer direction. More specifically, FIG. 11 illustrates a section including a p-type region 136, a p-type region 137, an n-type region 132, an n-type region 133, an n-type region 134 and an n-type region 135, in a direction 140 perpendicular to the charge transfer direction. In FIGS. 10 and 11, constituent elements equal to those in FIGS. 1 to 9 are not described in detail herein.

In FIG. 10, a region 23 includes an n-type region 6, a p-type region 130, a p-type region 131, a gate electrode 14 and a gate electrode 52, and corresponds to a horizontal CCD outlet. A region 25 includes an n-type region 33, an n-type region 16, the p-type region 130, the p-type region 131 and a gate electrode 53, and corresponds to a reset drain. A region 24 is sandwiched between the regions 23 and 25, and corresponds to a signal charge-voltage converter. The region 24 includes the n-type region 132, the n-type region 133, the n-type region 134, the n-type region 135, the p-type region 136, the p-type region 137 and a gate electrode 139.

In FIG. 11, the p-type region 130 is selectively formed in a p-type well 2 selectively formed in an n-type semiconductor substrate (hereinafter, simply referred to as “substrate”) 1. The p-type region 131 is selectively formed on a surface of the substrate 1 so as to come into contact with the p-type region 130. An oxide film 4 is selectively formed on the surface of the substrate 1, and a p-type region 3 is formed immediately below the oxide film 4. The p-type region 3 is connected to the p-type regions 130 and 131 in the substrate 1. The p-type region 136 is formed on the surface side of the substrate 1 so as to come into contact with the p-type region 130. The p-type region 137 for a contact with the substrate 1 is formed on the surface of the substrate 1 so as to come into contact with the p-type region 136. Herein, the p-type region 137 has a high concentration. The p-type region 136 serves as a channel of a junction transistor for performing signal charge-voltage conversion. The p-type region 130 and the p-type region 137 serve as a source and a drain of the junction transistor. The p-type region 130 has an impurity concentration equal to or higher than that of the p-type region 136. The p-type region 137 has an impurity concentration equal to or higher than that of the p-type region 136.

The n-type region 132 is formed on the surface of the substrate 1 so as to come into contact with one of ends of the p-type regions 136 and 137. The n-type region 134 is formed immediately below the n-type region 132 so as to come into contact with the aforementioned end of the p-type region 136. The n-type region 134 has an end which is opposite to the end coming into contact with the p-type region 136 and is located inward as compared with that of the n-type region 132.

The n-type region 133 is formed on the surface of the substrate 1 so as to come into contact with the other ends of the p-type regions 136 and 137. The n-type region 135 is formed immediately below the n-type region 133 so as to come into contact with the aforementioned end of the p-type region 136. The n-type region 135 has an end which is opposite to the end coming into contact with the p-type region 136 and is located inward as compared with that of the n-type region 133.

The p-type region 131 is formed at ends of the n-type regions 132 and 134, opposite to the ends coming into contact with the p-type regions 136 and 137, on the surface of the substrate 1. The p-type region 130 is formed immediately below the p-type region 131. The p-type region 131 is formed at ends of the n-type regions 133 and 135, opposite to the ends coming into contact with the p-type regions 136 and 137, on the surface of the substrate 1. The p-type region 130 is formed immediately below the p-type region 131. The p-type region 130 is also formed immediately below the n-type regions 134 and 135. Each of the n-type regions 134 and 135 is surrounded with the p-type region 131 and the p-type region 136.

A pair of the n-type regions 132 and 134 and a pair of the n-type regions 133 and 135 serve as gate electrodes of the junction transistor. Particularly, each of the n-type regions 134 and 135 can enhance signal charge-voltage conversion efficiency. A gate insulating film 138 is formed over the n-type region 132, the n-type region 133, the n-type region 134, the n-type region 135, the p-type region 131 and the oxide film 4 on the surface of the substrate 1. A gate electrode 139 is formed immediately above the gate insulating film 138 so as to entirely cover the n-type regions 132 to 135 and to partially cover the p-type region 131. Thus, it is possible to configure a signal charge-voltage converter having a junction transistor capable of readily improving an S/N ratio. In FIG. 11, chain lines 141 and 142 indicate currents flowing through the source of the junction transistor. A chain line 143 indicates a current flowing through the channel of the junction transistor. A straight line 149 indicates a dotted line passing through the n-type region 134, then-type region 135 and the p-type region 136. The straight line 149 includes the gate and the channel of the junction transistor. An arrow mark 144 indicates a width of the p-type region 136. The width of the p-type region 136 corresponds to a channel width of the junction transistor. At the channel width of the junction transistor, signal charge is subjected to voltage modulation. Arrow marks 145 and 146 indicate widths of the n-type regions 134 and 135.

Next, description will be given of a mechanism for improving signal charge-voltage conversion efficiency with reference to FIGS. 10 and 11.

In the junction transistor including the gate electrodes configured by the pair of the n-type regions 132 and 134 and the pair of the n-type regions 133 and 135, the channel configured by the p-type region 136, the source configured by the p-type region 130, and the drain configured by the p-type region 137, as described in the third embodiment, electrons (signal charge) fed into the region 24 corresponding to the signal charge-voltage converter are accumulated in the n-type regions 134 and 135 where a potential lowers at maximum. Thus, the channel width 144 of the junction transistor is modulated. Herein, it is effective that the channel width 144 of the junction transistor is equal to a thickness 147 of the n-type region 134 and a thickness 148 of the n-type region 135. In this embodiment, the thicknesses 147 and 148 are obtained in such a manner that a desirable depth and a desirable concentration are obtained by high energy ion implantation. As the thicknesses 147 and 148 are made small, a pinch-off voltage in the junction transistor can be made small. Additionally, a voltage amplitude upon performance of signal charge-voltage conversion can be made large. As a result, it is possible to obtain high signal charge-voltage conversion efficiency.

Further, the n-type regions 134 and 135 formed at the both ends of the p-type region 136 accumulate electrons (signal charge) and change potentials thereat. The change in potential directly exerts an influence on the n-type region 134, n-type region 135 and p-type region 136. Therefore, it is possible to further enhance signal charge-voltage conversion efficiency. Moreover, the widths 145 and 146 are made small to form an output voltage at a high concentration. Only by such operation, it is possible to readily configure a junction transistor capable of realizing desired voltage conversion characteristics at high efficiency and improving an S/N ratio.

According to the fourth embodiment of the present invention, as described above, a signal charge-voltage converter includes a first conductive type first diffusion layer selectively formed on a surface of a semiconductor substrate, a first conductive type second diffusion layer formed at a deep portion of the semiconductor substrate so as to come into contact with the first conductive type first diffusion layer, a second conductive type first diffusion layer formed on the surface of the semiconductor substrate so as to come into contact with one of ends of the first conductive type first diffusion layer, a second conductive type second diffusion layer formed immediately below the second conductive type first diffusion layer and formed immediately above the first conductive type second diffusion layer so as to have an end located inward as compared with an end of the second conductive type first diffusion layer opposite to an end coming into contact with the first conductive type first diffusion layer, a second conductive type third diffusion layer formed on the surface of the semiconductor substrate so as to come into contact with the other end of the first conductive type first diffusion layer, a second conductive type fourth diffusion layer formed immediately below the second conductive type third diffusion layer and formed immediately above the first conductive type second diffusion layer so as to have an end located inward as compared with an end of the second conductive type third diffusion layer opposite to an end coming into contact with the first conductive type first diffusion layer, a first gate electrode entirely formed over the second conductive type first diffusion layer with an insulating film interposed therebetween, and a second gate electrode entirely formed over the second conductive type third diffusion layer with the insulating film interposed therebetween. Thus, it is possible to readily configure a signal charge-voltage converter having a junction transistor capable of realizing voltage conversion characteristics at high efficiency and improving an S/N ratio.

### Fifth Embodiment

FIG. 12 is a plan view schematically illustrating a signal charge-voltage converter in a charge transfer device according to a fifth embodiment of the present invention. In FIG. 12, the charge transfer device according to the fifth embodiment includes a transfer channel and a reset drain in addition to the signal charge-voltage converter. FIG. 13 is a sectional view illustrating the signal charge-voltage converter in the charge transfer device according to the fifth embodiment, in a direction perpendicular to a charge transfer direction. More specifically, FIG. 13 illustrates a section including a p-type region 151, a p-type region 155, an n-type region 153, an n-type region 154 and an n-type semiconductor substrate (hereinafter, simply referred to as “substrate”) 150, in a direction 160 perpendicular to the charge transfer direction. In FIGS. 12 and 13, constituent elements equal to those in FIGS. 1 to 6 are not described in detail herein.

In FIG. 12, a region 23 includes an n-type region 6, the p-type region 151, a p-type region 152, a gate electrode 14 and a gate electrode 52, and corresponds to a horizontal CCD outlet. A region 25 includes an n-type region 33, an n-type region 16, the p-type region 151, the p-type region 152 and a gate electrode 53, and corresponds to a reset drain. A region 24 is sandwiched between the regions 23 and 25, and corresponds to a signal charge-voltage converter. The region 24 includes the n-type region 153, the n-type region 154, the substrate 150, the p-type region 151, the p-type region 155 and a gate electrode 157.

In FIG. 13, the p-type region 151 is selectively formed in the substrate 150. The p-type region 155 is formed on a surface side of the substrate 150 so as to come into contact with the p-type region 151. The n-type region 153 is formed at one of ends of the p-type region 155 so as to come into contact with the p-type region 155. The n-type region 153 is formed immediately above the p-type 151 and comes into contact with the p-type region 152 at an end thereof opposite to an end coming into contact with the p-type region 155. In other words, the n-type region 153 is surrounded with the p-type regions 151 and 152.

The n-type region 154 is formed at the other end of the p-type region 155 so as to come into contact with the p-type region 155. The n-type region 154 is formed immediately above the p-type region 151 and comes into contact with the p-type region 152 at an end thereof opposite to an end coming into contact with the p-type region 155. In other words, the n-type region 154 is surrounded with the p-type regions 151 and 152. The p-type region 151 serves as a channel of a junction transistor for performing signal charge-voltage conversion. The p-type region 155 serves as a contact with the substrate 150 and, also, serves as a drain of the junction transistor. Therefore, the p-type region 155 has an impurity concentration equal to or higher than that of the p-type region 151. The substrate 150, the n-type region 153 and the n-type region 154 serve as gate electrodes of the junction transistor. The p-type region 152 and the p-type region 151 come into contact with a p-type region 3 in such a positional relation that the p-type region 152 is located on the p-type region 151 when being seen from the surface of the substrate 150. An oxide film 4 is formed on the n-type region 3 on the surface of the substrate 150. A gate insulating film 156 is formed over the n-type region 153, the n-type region 154, the p-type region 152 and the oxide film 4 on the surface of the substrate 150. The gate electrode 157 is formed immediately above the gate insulating film 156 so as to entirely cover the n-type regions 153 and 154 and to partially cover the p-type region 152. Thus, it is possible to configure a signal charge-voltage converter having a junction transistor capable of readily improving an S/N ratio.

In FIG. 13, chain lines 158 and 159 indicate currents flowing through a source of the junction transistor. A chain line 161 indicates a current flowing through a channel of the junction transistor. A straight line 166 indicates a dotted line passing through the n-type region 153, the p-type region 151 and the substrate 150. In other words, the straight line 166 indicates a region including a gate and the channel of the junction transistor. An arrow mark 162 indicates a width of the p-type region 151. The width of the p-type region 151 corresponds to a channel width of the junction transistor. At the channel width of the junction transistor, signal charge is subjected to voltage modulation. Arrow marks 164 and 165 indicate widths of the n-type regions 153 and 154.

Next, description will be given of a mechanism for improving signal charge-voltage conversion efficiency with reference to FIGS. 12 to 14. FIG. 14 shows potential distribution in signal conversion performed by the charge transfer device according to the fifth embodiment. More specifically, FIG. 14 shows potential distribution before and after the signal conversion in the regions along the straight line 166. A straight line 178 indicates a region at each position along the straight line 166. A curve 170 indicates potential distribution before the signal conversion. Electrons (signal charge) fed into the region 24 corresponding to the signal charge-voltage converter are accumulated in the n-type regions 153 and 154 because the potential distribution is deep. Then, a minimum potential 172 changes into a potential 173. The potential distribution in the signal conversion varies as indicated by a curve 171. In response thereto, a potential at the p-type region 151 changes from a potential 175 into a potential 176. Thus, a channel current 161 in the junction transistor is modulated, and then is subjected to voltage conversion by an external load resistor 21. A potential applied to the substrate 150 is fixed at a potential 177 during the signal conversion. Herein, a p-type region, in particular, a p-type well is not formed immediately above the p-type region 151. Therefore, a depletion layer can be widened from a deep portion of the substrate 150 toward the p-type region 151 at a desired depth by the potential 177 applied to the substrate 150. This aids in widening of the depletion layer from the n-type regions 153 and 154 to the p-type region 151 by electrons (signal charge). As a result, it is possible to reduce a pinch-off voltage in the junction transistor. An applied voltage to the substrate 150 and a voltage amplitude in a case that signal charge is subjected to voltage conversion by the n-type regions 153 and 154 are limited; therefore, the junction transistor can be readily configured. Moreover, as the channel width 162 of the p-type region 151 corresponding to the channel of the junction transistor is made small, signal charge-voltage conversion efficiency can be enhanced. Further, the p-type region 151 can be formed independently of another p-type and n-type regions; therefore, it is possible to readily obtain high signal charge-voltage conversion efficiency. In addition, the signal charge-voltage converter has the junction transistor generating no noise and, therefore, can obtain an excellent S/N ratio. Thus, it is possible to readily configure a signal charge-voltage converter which is high in signal charge-voltage conversion efficiency and is excellent in S/N ratio.

According to the fifth embodiment, as described above, a signal charge-voltage converter includes a first conductive type first diffusion layer selectively formed on a surface of a semiconductor substrate, a first conductive type second diffusion layer formed at a deep portion of the semiconductor substrate so as to come into contact with the first conductive type first diffusion layer, a second conductive type first diffusion layer formed on the surface of the semiconductor substrate so as to come into contact with one of ends of the first conductive type first diffusion layer and to come into contact with the first conductive type second diffusion layer formed immediately therebelow, a second conductive type second diffusion layer formed on the surface of the semiconductor substrate so as to come into contact with the other end of the first conductive type first diffusion layer and to come into contact with the first conductive type second diffusion layer formed immediately therebelow, the semiconductor substrate coming into contact with the first conductive second diffusion layer formed immediately thereabove, a first gate electrode entirely formed over the second conductive type first diffusion layer with an insulating film interposed therebetween, and a second gate electrode entirely formed over the second conductive type second diffusion layer with the insulating film interposed therebetween. Thus, it is possible to readily configure a signal charge-voltage converter which is high in signal charge-voltage conversion efficiency and is excellent in S/N ratio.

### Sixth Embodiment

FIG. 15 is a plan view schematically illustrating a signal charge-voltage converter in a charge transfer device according to a sixth embodiment of the present invention. In FIG. 15, the charge transfer device according to the sixth embodiment includes a transfer channel and a reset drain in addition to the signal charge-voltage converter. FIG. 16 is a sectional view illustrating the signal charge-voltage converter in the charge transfer device according to the sixth embodiment, in a direction perpendicular to a charge transfer direction. More specifically, FIG. 16 illustrates a section including a p-type region 201, a p-type region 205, an n-type region 200, an n-type region 203 and an n-type region 204, in a direction 210 perpendicular to the charge transfer direction. In FIGS. 15 and 16, constituent elements equal to those in FIGS. 1 to 6 and 12 to 14 are not described in detail herein.

In FIG. 15, a region 23 includes an n-type region 6, the p-type region 201, a p-type region 202, a gate electrode 14 and a gate electrode 52, and corresponds to a horizontal CCD outlet. A region 25 includes an n-type region 33, an n-type region 16, the p-type region 201, the p-type region 202 and a gate electrode 53, and corresponds to a reset drain. A region 24 is sandwiched between the regions 23 and 25, and corresponds to a signal charge-voltage converter. The region 24 includes the n-type region 200, the n-type region 203, the n-type region 204, the p-type region 201, the p-type region 205, the p-type region 202 and a gate electrode 207.

In FIG. 16, the n-type region 200 is selectively formed in a p-type well 2 selectively formed in an n-type semiconductor substrate (hereinafter, simply referred to as “substrate”) 1. The p-type region 201 is formed on a surface side of the substrate 1 so as to come into contact with the n-type region 200. The p-type region 205 is formed on the surface side of the substrate 1 so as to come into contact with the p-type region 201. The n-type region 203 is formed at one of ends of the p-type region 205 so as to come into contact with the p-type region 205. The n-type region 203 is formed immediately above the p-type region 201 and comes into contact with the p-type region 202 at an end thereof opposite to an end coming into contact with the p-type region 205. In other words, the n-type region 203 is surrounded with the p-type regions 201 and 202. The n-type region 204 is formed at the other end of the p-type region 205 so as to come into contact with the p-type region 205. The n-type region 204 is formed immediately above the p-type region 201 and comes into contact with the p-type region 202 at an end thereof opposite to an end coming into contact with the p-type region 205. In other words, the n-type region 204 is surrounded with the p-type regions 201 and 202. The p-type region 201 serves as a channel of a junction transistor for performing signal charge-voltage conversion. The p-type region 205 serves as a contact with the substrate land, also, serves as a drain of the junction transistor. Therefore, the p-type region 205 has an impurity concentration equal to or higher than that of the p-type region 201. The n-type regions 200, 203 and 204 serve as gate electrodes of the junction transistor. The n-type region 200, the p-type region 201 and the p-type region 202 come into contact with a p-type region 3 in such a positional relation that the p-type region 201 is located on the p-type region 200 and the p-type region 202 is located on the p-type region 201 when being seen from the surface of the substrate 1. An oxide film 4 is formed on the p-type region 3 on the surface of the substrate 1. A gate insulating film 206 is formed over the n-type region 203, the n-type region 204, the p-type region 202 and the oxide film 4 on the surface of the substrate 1. The gate electrode 207 is formed immediately above the gate insulating film 206 so as to entirely cover the n-type regions 203 and 204 and to partially cover the p-type region 202. Thus, it is possible to configure a signal charge-voltage converter having a junction transistor capable of readily improving an S/N ratio.

In FIG. 16, chain lines 208 and 209 indicate currents flowing through a source of the junction transistor. A chain line 211 indicates a current flowing through a channel of the junction transistor. A straight line 216 indicates a dotted line passing through the n-type region 200, the n-type region 203 and the p-type region 201. In other words, the straight line 216 indicates a region including a gate and the channel of the junction transistor. An arrow mark 212 indicates a width of the p-type region 201. The width of the p-type region 201 corresponds to a channel width of the junction transistor. At the channel width of the junction transistor, signal charge is subjected to voltage modulation. Arrow marks 214 and 215 indicate widths of the n-type regions 203 and 204.

Next, description will be given of a mechanism for improving signal charge-voltage conversion efficiency with reference to FIGS. 15 to 17. FIG. 17 shows potential distribution in signal conversion performed by the charge transfer device according to the sixth embodiment. More specifically, FIG. 17 shows potential distribution before and after the signal conversion in the regions along the straight line 216. A straight line 228 indicates a region at each position along the straight line 216. A curve 220 indicates potential distribution before the signal conversion. Electrons (signal charge) fed into the region 24 corresponding to the signal charge-voltage converter are accumulated in the n-type regions 203 and 204 because the potential distribution is deep. Herein, a minimum potential 222 changes into a potential 223, and the potential distribution in the signal conversion varies as indicated by a curve 221. In response thereto, a potential at the p-type region 201 changes from a potential 225 into a potential 226. Thus, a channel current 211 in the junction transistor is modulated, and then is subjected to voltage conversion by an external load resistor 21. A potential applied to the substrate 1 is fixed at a potential 227 during the signal conversion. Herein, the n-type region 200 is formed immediately below the p-type region 201. Therefore, a depletion layer can be widened from then-type region 200 toward the p-type region 201 at a desired depth by the potential 227 applied to the n-type region 200. This aids in widening of the depletion layer from the n-type regions 203 and 204 to the p-type region 201 by electrons (signal charge). As a result, it is possible to reduce a pinch-off voltage in the junction transistor. An applied voltage to the n-type region 200 and a voltage amplitude in a case that signal charge is subjected to voltage conversion by the n-type regions 203 and 204 are limited; therefore, the junction transistor can be readily configured. Moreover, as the channel width 212 of the p-type region 201 corresponding to the channel of the junction transistor is made small, signal charge-voltage conversion efficiency can be enhanced. Further, the p-type region 201 can be formed independently of another p-type and n-type regions; therefore, it is possible to readily obtain high signal charge-voltage conversion efficiency. In addition, the signal charge-voltage converter has the junction transistor generating no noise and, therefore, can obtain an excellent S/N ratio. Thus, it is possible to readily configure a signal charge-voltage converter which is high in signal charge-voltage conversion efficiency and is excellent in S/N ratio.

According to the sixth embodiment, as described above, a signal charge-voltage converter includes a first conductive type first diffusion layer selectively formed on a surface of a semiconductor substrate, a first conductive type second diffusion layer formed at a deep portion of the semiconductor substrate so as to come into contact with the first conductive type first diffusion layer, a second conductive type first diffusion layer formed on the surface of the semiconductor substrate so as to come into contact with one of ends of the first conductive type first diffusion layer and to come into contact with the first conductive type second diffusion layer formed immediately therebelow, a second conductive type second diffusion layer formed on the surface of the semiconductor substrate so as to come into contact with the other end of the first conductive type first diffusion layer and to come into contact with the first conductive type second diffusion layer formed immediately therebelow, a second conductive type third diffusion layer coming into contact with the first conductive second diffusion layer formed immediately thereabove, a first gate electrode entirely formed over the second conductive type first diffusion layer with an insulating film interposed therebetween, and a second gate electrode entirely formed over the second conductive type second diffusion layer with the insulating film interposed therebetween. Thus, it is possible to readily configure a signal charge-voltage converter which is high in signal charge-voltage conversion efficiency and is excellent in S/N ratio.

### Seventh Embodiment

FIG. 18 is a plan view schematically illustrating a signal charge-voltage converter in a charge transfer device according to a seventh embodiment of the present invention. In FIG. 18, the charge transfer device according to the seventh embodiment includes a transfer channel and a reset drain in addition to the signal charge-voltage converter. FIG. 19 is a sectional view illustrating the signal charge-voltage converter in the charge transfer device according to the seventh embodiment, in a direction perpendicular to a charge transfer direction. More specifically, FIG. 19 illustrates a section including a p-type region 241, a p-type region 247, an n-type region 240, an n-type region 243, an n-type region 244, an n-type region 245 and an n-type region 246, in a direction 250 perpendicular to the charge transfer direction. In FIGS. 18 and 19, constituent elements equal to those in FIGS. 1 to 6 and 12 to 17 are not described in detail herein.

In FIG. 18, a region 23 includes an n-type region 6, the p-type region 241, a p-type region 242, a gate electrode 14 and a gate electrode 52, and corresponds to a horizontal CCD outlet. A region 25 includes an n-type region 33, an n-type region 16, the p-type region 241, the p-type region 242 and a gate electrode 53, and corresponds to a reset drain. A region 24 is sandwiched between the regions 23 and 25, and corresponds to a signal charge-voltage converter. The region 24 includes the n-type region 240, the n-type region 243, the n-type region 244, the n-type region 245, the n-type region 246, the p-type region 241, the p-type region 247 and a gate electrode 249.

In FIG. 19, the n-type region 240 is selectively formed in a p-type well 2 selectively formed in an n-type semiconductor substrate (hereinafter, simply referred to as “substrate”) 1. The p-type region 241 is formed on a surface side of the substrate 1 so as to come into contact with the n-type region 240. The p-type region 247 is formed on the surface side of the substrate 1 so as to come into contact with the p-type region 241. The n-type region 243 is formed at one of ends of the p-type region 247 and on the surface of the substrate 1 so as to come into contact with the p-type region 247. The n-type region 245 is formed immediately above the n-type region 243 so as to come into contact with the end of the p-type region 247 coming into contact with the n-type region 243. The n-type region 245 has an end which is opposite to an end coming into contact with the p-type region 247 and is located inward as compared with that of the n-type region 243. The n-type regions 243 and 245 are surrounded with the p-type region 241 formed immediately below the n-type region 245 and the p-type region 242 formed at ends thereof opposite to the ends coming into contact with the p-type region 247. The n-type region 244 is formed at the other end of the p-type region 247 and on the surface of the substrate 1 so as to come into contact with the p-type region 247. The n-type region 246 is formed immediately below the n-type region 244 so as to come into contact with the end of the p-type region 247 coming into contact with the n-type region 244. The n-type region 246 has an end which is opposite to the end coming into contact with the p-type region 247 and is located inward as compared with that of the n-type region 244. The n-type regions 244 and 246 are surrounded with the p-type region 241 formed immediately below the n-type region 246 and the p-type region 242 coming into contact with ends thereof opposite to the ends coming into contact with the p-type region 247. The p-type region 241 serves as a channel of a junction transistor for performing signal charge-voltage conversion. The p-type region 247 serves as a contact with the substrate 1 and, also, serves as a drain of the junction transistor. Therefore, the p-type region 247 has an impurity concentration equal to or higher than that of the p-type region 241. A pair of the n-type region 243 and the n-type region 245, a pair of the n-type region 244 and the n-type region 246 and the n-type region 240 serve as gate electrodes of the junction transistor.

The n-type region 240, the p-type region 241 and the p-type region 242 come into contact with a p-type region 3 in such a positional relation that the p-type region 241 is located on the p-type region 240 and the p-type region 242 is located on the p-type region 241 when being seen from the surface of the substrate 1.

An oxide film 4 is formed on the p-type region 3 on the surface of the substrate 1. Agate insulating film 248 is formed over the n-type region 243, the n-type region 244, the p-type region 242 and the oxide film 4 on the surface of the substrate 1. The gate electrode 249 is formed immediately above the gate insulating film 248 so as to entirely cover the n-type regions 243 and 244 and to partially cover the p-type region 242. Thus, it is possible to configure a signal charge-voltage converter having a junction transistor capable of readily improving an S/N ratio.

In FIG. 19, chain lines 251 and 252 indicate currents flowing through a source of the junction transistor. A chain line 253 indicates a current flowing through a channel of the junction transistor. A straight line 258 indicates a dotted line passing through the n-type region 240, the n-type region 243, the n-type region 245 and the p-type region 241. In other words, the straight line 258 indicates a region including a gate and the channel of the junction transistor. An arrow mark 254 indicates a width of the p-type region 241. The width of the p-type region 241 corresponds to a channel width of the junction transistor. At the channel width of the junction transistor, signal charge is subjected to voltage modulation. Arrow marks 256 and 257 indicate widths of the n-type regions 245 and 246.

Next, description will be given of a mechanism for improving signal charge-voltage conversion efficiency with reference to FIGS. 18 to 20. FIG. 20 shows potential distribution in signal conversion performed by the charge transfer device according to the seventh embodiment. More specifically, FIG. 20 shows potential distribution before and after the signal conversion in the regions along the straight line 258. A straight line 268 indicates a region at each position along the straight line 258. A curve 260 indicates potential distribution before the signal conversion. Electrons (signal charge) fed into the region 24 corresponding to the signal charge-voltage converter are accumulated in the n-type regions 245 and 246 where a potential becomes high at maximum. Herein, a minimum potential 262 changes into a potential 263, and the potential distribution in the signal conversion varies as indicated by a curve 261. In response thereto, a potential at the p-type region 241 changes from a potential 265 into a potential 266. Thus, a channel current 253 in the junction transistor is modulated, and then is subjected to voltage conversion by an external load resistor 21. A potential applied to the substrate 1 is fixed at a potential 267 during the signal conversion. Herein, the n-type region 240 is formed immediately below the p-type region 241. Therefore, a depletion layer can be widened from the n-type region 240 toward the p-type region 241 at a desired depth by the potential 267 applied to the n-type region 240. This aids in widening of the depletion layer from the n-type regions 243 and 244 to the p-type region 241 by electrons (signal charge). As a result, it is possible to reduce a pinch-off voltage in the junction transistor. An applied voltage to then-type region 240 and a voltage amplitude in a case that signal charge is subjected to voltage conversion by the n-type regions 245 and 246 are limited; therefore, the junction transistor can be readily configured. Moreover, as the channel width 254 of the p-type region 241 corresponding to the channel of the junction transistor is made small, signal charge-voltage conversion efficiency can be enhanced. Further, the p-type region 241 can be formed independently of another p-type and n-type regions; therefore, it is possible to readily obtain high signal charge-voltage conversion efficiency. In addition, the signal charge-voltage converter has the junction transistor generating no noise and, therefore, can obtain an excellent S/N ratio. Thus, it is possible to readily configure a signal charge-voltage converter which is high in signal charge-voltage conversion efficiency and is excellent in S/N ratio.

According to the seventh embodiment, as described above, a signal charge-voltage converter includes a first conductive type first diffusion layer selectively formed on a surface of a semiconductor substrate, a first conductive type second diffusion layer formed at a deep portion of the semiconductor substrate so as to come into contact with the first conductive type first diffusion layer, a second conductive type first diffusion layer formed on the surface of the semiconductor substrate so as to come into contact with one of ends of the first conductive type first diffusion layer, a second conductive type second diffusion layer coming into contact with the second conductive type first diffusion layer formed immediately thereabove and coming into contact with the first conductive type second diffusion layer formed immediately therebelow, a second conductive type third diffusion layer formed on the surface of the semiconductor substrate so as to come into contact with the other end of the first conductive type first diffusion layer, a second conductive type fourth diffusion layer coming into contact with the second conductive type third diffusion layer formed immediately thereabove and coming into contact with the first conductive type second diffusion layer formed immediately therebelow, a second conductive type fifth diffusion layer coming into contact with the first conductive type second diffusion layer formed immediately thereabove, a first gate electrode entirely formed over the second conductive type first diffusion layer with an insulating film interposed therebetween, and a second gate electrode entirely formed over the second conductive type second diffusion layer with the insulating film interposed therebetween. Thus, it is possible to readily configure a signal charge-voltage converter which is high in signal charge-voltage conversion efficiency and is excellent in S/N ratio.

### Eighth Embodiment

FIG. 21 is a plan view schematically illustrating a signal charge-voltage converter in a charge transfer device according to an eighth embodiment of the present invention. In FIG. 21, the charge transfer device according to the eighth embodiment includes a transfer channel and a reset drain in addition to the signal charge-voltage converter. FIG. 22 is a sectional view illustrating the signal charge-voltage converter in the charge transfer device according to the eighth embodiment, in a direction parallel with a charge transfer direction. More specifically, FIG. 22 illustrates a section including an n-type region 280 serving as a gate electrode of a junction transistor, in a direction 281 parallel with the charge transfer direction. In FIGS. 21 and 22, constituent elements equal to those in FIGS. 1 to 6 are not described in detail herein.

In FIG. 21, a region 23 includes an n-type region 6, a p-type region 5, a gate electrode 14 and a gate electrode 52, and corresponds to a horizontal CCD outlet. A region 25 includes the n-type region 280, an n-type region 16, the p-type region 5 and a gate electrode 53, and corresponds to a rest drain. A region 24 is sandwiched between the regions 23 and 25, and corresponds to a signal charge-voltage converter. In the region 24, the junction transistor is configured for performing voltage conversion on signal charge. The n-type region 280 serves as the gate electrode of the junction transistor. The p-type electrode 51 serves as both a channel and a drain of the junction transistor. The p-type region 5 serves as a source of the junction transistor.

In FIG. 22, the n-type region 6 serving as the horizontal CCD channel is formed on a surface side of an n-type semiconductor substrate (hereinafter, simply referred to as “substrate”) 1 so as to come into contact with the p-type region 5 selectively formed at a deep portion of the substrate 1. The n-type region 280 has one of ends coming into contact with the n-type region 6 and the other end coming into contact with the n-type region 16, and is formed immediately above the p-type region 5. A gate insulating film 11 is formed over the n-type region 6, the n-type region 280 and the n-type region 16 on the surface of the substrate 1. A gate electrode 15 is formed on the n-type region 280 with the gate insulating film 11 interposed therebetween. Likewise, in order to reset signal charge, the gate electrode 53 is formed on the n-type region 280 with the gate insulating film 11 interposed therebetween. The gate electrode 15 and the gate electrode 53 adjoin to each other with an oxide film 17 interposed therebetween. Thus, it is possible to configure a signal charge-voltage converter having a junction transistor capable of readily improving an S/N ratio.

Next, description will be given of a mechanism for improving an S/N ratio with reference to FIGS. 21 and 22. The n-type region 280 is the gate electrode of the junction transistor for performing signal charge-voltage conversion. In order to transfer electrons from the region 23 to the region 24, corresponding to the signal charge-voltage converter, without loss and to control a gate potential at the junction transistor within an operating voltage range, the gate electrode 15 can be externally applied with a desired voltage. Therefore, a potential barrier is not generated at a portion which is located between the n-type region 6 and the n-type region 280 and is located immediately below a boundary between the gate electrode 52 and gate electrode 15. As a result, charge transfer can be performed without fail. In a state that there is no electron, the n-type region 280 is depleted. When electrons (signal charge) are fed from the n-type region 6 serving as the horizontal channel in the region 23 into the n-type region 280, a potential at the n-type region 280 is modulated negatively. Thus, a potential at the p-type region 51 serving as the channel of the junction transistor is modulated, and the signal charge can be subjected to voltage conversion. After performance of the voltage conversion, the signal charge is discharged to the n-type region 16 serving as the reset drain when the gate electrode 53 serving as the reset gate is applied with a pulse voltage. In this embodiment, the n-type region 280 serves as both the gate electrode and the reset drain of the junction transistor; therefore, there is no joint in an n-type region located immediately below a boundary between the gate electrode 15 and the gate electrode 53. As a result, there occurs no discontinuity of impurity concentrations, so that a potential barrier is not generated at the n-type region located immediately below the boundary between the gate electrode 15 and the gate electrode 53. Accordingly, even when electrons are discharged to the reset drain 16, there is generated no reset noise due to remaining electrons after performance of the charge discharge; thus, it is possible to realize a high S/N ratio.

According to the eighth embodiment, as described above, a signal charge-voltage converter includes a first conductive type first diffusion layer selectively formed on a surface of a semiconductor substrate, a second conductive type first diffusion layer formed so as to come into contact with three ends of the first conductive type first diffusion layer, a first gate electrode entirely formed over the first conductive type first diffusion layer and the second conductive type first diffusion layer on the surface of the semiconductor substrate with a first insulating film interposed therebetween, and a second gate electrode formed at an end of the first gate electrode and on the first insulating film with a second insulating film interposed therebetween. Herein, the second conductive type first diffusion layer extends beyond the first gate electrode. Thus, it is possible to maintain a high S/N ratio without generation of reset noise.

### Ninth Embodiment

FIG. 23 is a plan view schematically illustrating a signal charge-voltage converter in a charge transfer device according to a ninth embodiment of the present invention. In FIG. 23, the charge transfer device according to the ninth embodiment includes a transfer channel and a reset drain in addition to the signal charge-voltage converter. FIG. 24 is a sectional view illustrating the signal charge-voltage converter in the charge transfer device according to the ninth embodiment, in a direction parallel with a charge transfer direction. More specifically, FIG. 24 illustrates a section including an n-type region 300 serving as a gate electrode of a junction transistor, in a direction 301 parallel with the charge transfer direction. In FIGS. 23 and 24, constituent elements equal to those in FIGS. 1 to 6 are not described in detail herein.

In FIG. 23, a region 23 includes an n-type region 6, a p-type region 5, a gate electrode 11 and a gate electrode 52, and corresponds to a horizontal CCD outlet. A region 25 includes the n-type region 300, an n-type region 16, the p-type region 5 and a gate electrode 53, and corresponds to a reset drain. A region 24 is sandwiched between the regions 23 and 25, and corresponds to a signal charge-voltage converter. In the region 24, the junction transistor is configured for performing voltage conversion on signal charge. The n-type region 300 serves as the gate electrode of the junction transistor. The p-type region 51 serves as both a channel and a drain of the junction transistor. The p-type region 5 serves as a source of the junction transistor. Arrow marks 302 and 303 indicate widths each defined for inputting signals to the region 24 corresponding to the signal charge-voltage converter. Arrow marks 304 and 305 indicate widths each defined for outputting signals from the region 24. The arrow marks 302 and 304 correspond to each other and the arrow marks 303 and 305 correspond to each other in a signal input/output relation.

In FIG. 24, the n-type region 6 serving as the horizontal CCD channel is formed on a surface side of an n-type semiconductor substrate (hereinafter, simply referred to as “substrate”) 1 so as to come into contact with the p-type region 5 selectively formed at a deep portion of the substrate 1. The n-type region 300 has one of ends coming into contact with the n-type region 6 and the other end coming into contact with the n-type region 16, and is formed immediately above the p-type region 5. A gate insulating film 11 is formed over the n-type region 6, the n-type region 300 and the n-type region 16 on the surface of the substrate 1. A gate electrode 15 is formed on the n-type region 300 with the gate insulating film 11 interposed therebetween. Likewise, in order to reset signal charge, the gate electrode 53 is formed on then-type region 300 with the gate insulating film 11 interposed therebetween. The gate electrode 15 and the gate electrode 53 adjoin to each other with an oxide film 17 interposed therebetween. Thus, it is possible to configure a signal charge-voltage converter having a junction transistor capable of readily improving an S/N ratio.

Next, description will be given of a mechanism for improving an S/N ratio with reference to FIGS. 23 and 24. The n-type region 300 is the gate electrode of the junction transistor for performing signal charge-voltage conversion. In order to transfer electrons from the region 23 to the region 24, corresponding to the signal charge-voltage converter, without loss and to control a gate potential at the junction transistor within an operating voltage range, the gate electrode 15 can be externally applied with a desired voltage. Therefore, a potential barrier is not generated at a portion which is located between the n-type region 6 and the n-type region 300 and is located immediately below a boundary between the gate electrode 52 and gate electrode 15. As a result, charge transfer can be performed without fail. In a state that there is no electron, the n-type region 300 is depleted. When electrons (signal charge) are fed from then-type region 6 serving as the horizontal channel in the region 23 into the n-type region 300, a potential at the n-type region 300 is modulated negatively. Thus, a potential at the p-type region 51 serving as the channel of the junction transistor is modulated, and the signal charge can be subjected to voltage conversion. After performance of the voltage conversion, the signal charge is discharged to the n-type region 16 serving as the reset drain when the gate electrode 53 serving as the reset gate is applied with a pulse voltage. In this embodiment, the width 304 is wider than the width 302 and the width 305 is wider than the width 303. In other words, the width for signal output from the region 24 corresponding to the signal charge-voltage converter is wider than the width for signal input to the region 24. As a result, in the region 24, a potential gradient can be formed toward the region 25 corresponding to the reset drain. Therefore, it is possible to smoothly discharge electrons from the region 24, corresponding to the signal charge-voltage converter, to the region 25 without loss. Accordingly, even when electrons are discharged to the reset drain 16, there is generated no reset noise due to remaining electrons after performance of the charge discharge; thus, it is possible to realize a high S/N ratio.

According to the ninth embodiment, as described above, a signal charge-voltage converter includes a first conductive type first diffusion layer selectively formed on a surface of a semiconductor substrate, a second conductive type first diffusion layer formed so as to come into contact with three ends of the first conductive type first diffusion layer, a first gate electrode entirely formed over the first conductive type first diffusion layer and the second conductive type first diffusion layer on the surface of the semiconductor substrate with a first insulating film interposed therebetween, and a second gate electrode formed at an end of the first gate electrode and on the first insulating film with a second insulating film interposed therebetween. Herein, the second conductive type first diffusion layer extends beyond the second gate electrode such that the second conductive type first diffusion layer intersecting the second gate electrode has a width on a first gate electrode side shorter than that on an opposite side. Thus, it is possible to maintain a high S/N ratio without generation of reset noise.

What is claimed is:

1. A charge transfer device comprising:
a semiconductor substrate;
a horizontal transfer CCD transferring received signal charge in a horizontal direction;
a signal charge-voltage converter converting the signal charge transferred from the horizontal transfer CCD into a signal voltage; and
a reset drain discharging the signal charge,
the horizontal transfer CCD, the signal charge-voltage converter and the reset drain being formed on the semiconductor substrate while adjoining to each other, wherein
the signal charge-voltage converter includes:
a first conductive type first diffusion layer selectively formed on a surface of the semiconductor substrate;
a second conductive type first diffusion layer formed on the surface of the semiconductor substrate so as to come into contact with one of ends of the first conductive type first diffusion layer;
a second conductive type second diffusion layer formed on the surface of the semiconductor substrate so as to come into contact with the other end of the first conductive type first diffusion layer;
a first gate electrode entirely formed over the first conductive type first diffusion layer, the second conductive type first diffusion layer and the second conductive type second diffusion layer with a first insulating film interposed therebetween;
a second gate electrode formed at one of ends of the first gate electrode and on the first insulating film with a second insulating film interposed therebetween; and
a third gate electrode formed at the other end of the first gate electrode and on the first insulating film with the second insulating film interposed therebetween, and
the first conductive type first diffusion layer extends to a portion located immediately below one of the second and third gate electrodes.

2. The charge transfer device according to claim 1, wherein
the first conductive type first diffusion layer extends to portions located immediately below both the second and third gate electrodes.

3. A charge transfer device comprising:
a semiconductor substrate;
a horizontal transfer CCD transferring received signal charge in a horizontal direction;
a signal charge-voltage converter converting the signal charge transferred from the horizontal transfer CCD into a signal voltage; and
a reset drain discharging the signal charge,
the horizontal transfer CCD, the signal charge-voltage converter and the reset drain being formed on the semiconductor substrate while adjoining to each other, wherein
the signal charge-voltage converter includes:
a first conductive type first diffusion layer selectively formed on a surface of the semiconductor substrate;
a second conductive type first diffusion layer formed on the surface of the semiconductor substrate so as to come into contact with one of ends of the first conductive type first diffusion layer;
a second conductive type second diffusion layer formed on the surface of the semiconductor substrate so as to come into contact with the other end of the first conductive type first diffusion layer;
a first gate electrode entirely formed over the first conductive type first diffusion layer, the second conductive type first diffusion layer and the second conductive type second diffusion layer with a first insulating film interposed therebetween;
a second gate electrode formed at one of ends of the first gate electrode and on the first insulating film with a second insulating film interposed therebetween, the second gate electrode having a triangular notch formed at a center thereof adjoining to the first gate electrode; and
a third gate electrode formed at the other end of the first gate electrode and on the first insulating film with the second insulating film interposed therebetween,
the end of the first conductive type first diffusion layer is formed into a triangular shape corresponding with the triangular notch of the second gate electrode, and
the triangular notch of the second gate electrode has a side face opposing that of the triangular end of the first conductive type first diffusion layer in parallel, with the first insulating film interposed therebetween.

4. The charge transfer device according to claim 3, wherein
the third gate electrode has a triangular notch formed at a center thereof adjoining to the first gate electrode,
the end of the first conductive type first diffusion layer is formed into a triangular shape corresponding with the triangular notch of the third gate electrode, and
the triangular notch of the third gate electrode has a side face opposing that of the triangular end of the first conductive type first diffusion layer in parallel, with the first insulating film interposed therebetween.

5. A charge transfer device comprising:
a semiconductor substrate;
a horizontal transfer CCD transferring received signal charge in a horizontal direction;
a signal charge-voltage converter converting the signal charge transferred from the horizontal transfer CCD into a signal voltage; and
a reset drain discharging the signal charge,
the horizontal transfer CCD, the signal charge-voltage converter and the reset drain being formed on the semiconductor substrate while adjoining to each other, wherein
the signal charge-voltage converter includes:
a first conductive type first diffusion layer selectively formed on a surface of the semiconductor substrate;
a first conductive type second diffusion layer formed at a deep portion of the semiconductor substrate so as to come into contact with the first conductive type first diffusion layer;
a second conductive type first diffusion layer formed on the surface of the semiconductor substrate so as to come into contact with one of ends of the first conductive type first diffusion layer and to come into contact with the first conductive type second diffusion layer formed immediately therebelow;
a second conductive type second diffusion layer formed so as to come into contact with an end of the second conductive type first diffusion layer opposite to an end coming into contact with the first conductive type first diffusion layer;
a second conductive type third diffusion layer formed on the surface of the semiconductor substrate so as to come into contact with an end of the first conductive type first diffusion layer opposite to the end coming into contact with the second conductive type first diffusion layer and to come into contact with the first conductive type second diffusion layer formed immediately therebelow;
a second conductive type fourth diffusion layer formed so as to come into contact with an end of the second conductive type third diffusion layer opposite to the end coming into contact with the first conductive type first diffusion layer;
a first conductive type third diffusion layer formed on the surface of the semiconductor substrate so as to come into contact with the second conductive type first diffusion layer, the second conductive type second diffusion layer, the second conductive type third diffusion layer and the second conductive type fourth diffusion layer and to come into contact with the first conductive type second diffusion layer formed immediately therebelow; and
a gate electrode entirely formed over the second conductive type first diffusion layer, the second conductive type second diffusion layer, the second conductive type third diffusion layer and the second conductive type fourth diffusion layer with an insulating film interposed therebetween.

6. The charge transfer device according to claim 1, wherein
the first conductive type diffusion layer is a p-type diffusion layer and the second conductive type diffusion layer is an n-type diffusion layer.

7. The charge transfer device according to claim 2, wherein
the first conductive type diffusion layer is a p-type diffusion layer and the second conductive type diffusion layer is an n-type diffusion layer.

8. The charge transfer device according to claim 3, wherein
the first conductive type diffusion layer is a p-type diffusion layer and the second conductive type diffusion layer is an n-type diffusion layer.

9. The charge transfer device according to claim 4, wherein
the first conductive type diffusion layer is a p-type diffusion layer and the second conductive type diffusion layer is an n-type diffusion layer.

10. The charge transfer device according to claim 5, wherein
the first conductive type diffusion layer is a p-type diffusion layer and the second conductive type diffusion layer is an n-type diffusion layer.

11. The charge transfer device according to claim 1, wherein
the first conductive type diffusion layer is an n-type diffusion layer and the second conductive type diffusion layer is a p-type diffusion layer.

12. The charge transfer device according to claim 2, wherein
the first conductive type diffusion layer is an n-type diffusion layer and the second conductive type diffusion layer is a p-type diffusion layer.

13. The charge transfer device according to claim 3, wherein
the first conductive type diffusion layer is an n-type diffusion layer and the second conductive type diffusion layer is a p-type diffusion layer.

14. The charge transfer device according to claim 4, wherein
the first conductive type diffusion layer is an n-type diffusion layer and the second conductive type diffusion layer is a p-type diffusion layer.

15. The charge transfer device according to claim 5, wherein
the first conductive type diffusion layer is an n-type diffusion layer and the second conductive type diffusion layer is a p-type diffusion layer.
